(19) United States
(12) Patent Application Publication
(10) Pub. No.: US 2018/0138407 A1
(43) Pub. Date: May 17, 2018

(54) FOUR-COORDINATE BORON COMPOUNDS

(71) Applicants: Dow Global Technologies LLC, Midland, MI (US); Rohm and Haas Electronic Materials LLC, Marlborough, MA (US); Rohm and Haas Electronic Materials Korea Ltd., Cheonan (KR)

(72) Inventors: Thomas P. Clark, Midland, MI (US); David S. Laitar, Midland, MI (US); Sukrit Mukhopadhyay, Midland, MI (US); Aaron A. Rachford, South Grafton, MA (US); Robert DJ Froese, Midland, MI (US); David D. Devore, Midland, MI (US); Bethany Neilson, Manvel, TX (US); Jeong-Hwan Jeon, Gwangju-si (KR); Hong-Yeop Na, Seoul (KR)

(21) Appl. No.: 15/567,987

(22) PCT Filed: Apr. 22, 2016
(86) PCT No.: PCT/US2016/028801

§ 371 Date: Oct. 20, 2017

Related U.S. Application Data
(60) Provisional application No. 62/155,743, filed on May 1, 2015.

(51) Int. Cl. H01L 51/00; C07F 5/02; C09K 11/06

(52) U.S. Cl. CPC H01L 51/008; C07F 5/02; C09K 11/06; H01L 51/5016; H01L 51/0072; C09K 2211/1022; H01L 51/0067

(57) ABSTRACT

A compound having a four-coordinate boron atom to which is connected a first C₃-C₂₅ substituent, a second C₃-C₂₅ substituent and a bridging substituent comprising from eight to forty non-hydrogen atoms and having two bonds to the boron atom;

wherein: (i) each of the first and second C₃-C₂₅ substituents is bonded to the boron atom through a carbon, nitrogen or oxygen atom, and, optionally the first and second C₃-C₂₅ substituents are connected to form a single substituent having two bonds to the boron atom; (ii) at least one of the first and second C₃-C₂₅ substituents is a C₆-C₂₅ aromatic substituent; (iii) said aromatic substituent comprises at least one nitrogen atom which is bonded only to carbon or boron atoms; and (iv) the bridging substituent has at least one oxygen, nitrogen, sulfur or phosphorus atom bonded to the boron atom and at least one aromatic ring.

This invention relates to new four-coordinate boron compounds useful as emitters in organic light-emitting diode (OLED) displays.

Four-coordinate boron compounds potentially useful in OLED displays are known. For example, WO2013/136978 discloses a compound having the structure

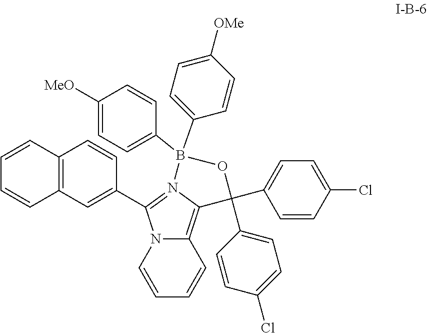

However, this reference does not disclose the compounds claimed herein. There is a need for emitters having a higher efficiency. The problem addressed by this invention is to find additional emitter compounds useful in OLED displays, and thermally activated delayed fluorescent (TADF) emitters in particular.

### STATEMENT OF INVENTION

The present invention provides a compound having a four-coordinate boron atom to which is connected a first C₃-C₂₅ substituent, a second C₃-C₂₅ substituent and a bridging substituent comprising from eight to forty non-hydrogen atoms and having two bonds to the boron atom;

wherein: (i) each of the first and second C₃-C₂₅ substituents is bonded to the boron atom through a carbon, nitrogen or oxygen atom, and, optionally the first and second C₃-C₂₅ substituents are connected to form a single substituent having two bonds to the boron atom; (ii) at least one of the first and second C₃-C₂₅ substituents is a C₆-C₂₅ aromatic substituent; (iii) said aromatic substituent comprises at least one nitrogen atom which is bonded only to carbon or boron atoms; and (iv) the bridging substituent has at least one oxygen, nitrogen, sulfur or phosphorus atom bonded to the boron atom and at least one aromatic ring.

### DETAILED DESCRIPTION

Percentages are weight percentages (wt %) and temperatures are in ° C., unless specified otherwise. Experimental work was carried out at room temperature (20-25° C.), unless otherwise specified. “Dopant” refers to a material that undergoes radiative emission from an excited state. This excited state can be generated by application of electrical current in an electroluminescent device and is either singlet or triplet in character. The term “fluorescent emission,” as used herein, refers to radiative emission from a singlet excited state. The term “phosphorescent emission,” as used herein, refers to radiative emission from a triplet excited state. For a dopant that undergoes primarily fluorescent emission, the term “triplet harvesting,” as used herein, refers to the ability to also harvest triplet excitons. The term “thermally activated delayed fluorescence (TADF),” as used herein, refers to fluorescent emission utilizing triplet harvesting, enabled by a thermally accessible singlet excited state. “Host” and like terms refer to a material that is doped with a dopant. The opto-electrical properties of the host material may differ based on which type of dopant (Phosphorescent or Fluorescent) is used. For Fluorescent dopants, the assisting host materials should have good spectral overlap between adsorption of the dopant and emission of the host to induce good Forster transfer to dopants. For Phosphorescent dopants and TADF dopants, the assisting host materials should have high triplet energies to confine triplets on the dopant.

An “alkyl” group is a substituted or unsubstituted hydrocarbyl group having from one to twenty-two carbon atoms in a linear, branched or cyclic arrangement. Preferably, alkyl groups are saturated. Preferably, alkyl groups are unsubstituted. Preferably, alkyl groups are linear or branched, i.e., acyclic. Preferably, each alkyl substituent is not a mixture of different alkyl groups, i.e., it comprises at least 98% of one particular alkyl group. An “aromatic substituent” is a group containing at least one aromatic ring. Where hydrogen atoms are present in the compounds of this invention, they can be partially or completely replaced by deuterium atoms, although hydrogen (i.e., the naturally occurring isotopic mixture) is preferred. “Non-hydrogen atoms” are atoms having atomic number greater than one, preferably greater than five. Preferably, non-hydrogen atoms are carbon, nitrogen, oxygen, halogens, silicon, sulfur and phosphorus; preferably carbon, nitrogen, oxygen, fluorine and silicon Preferably, the compounds of this invention are neutral, i.e., they have no overall charge. Preferably, one of the four bonds to boron is a dative bond.

Preferably, the compounds of this invention have a molecular weight from 400 to 900, preferably from 440 to 850, preferably from 500 to 800.

In compounds of this invention the first and second C₃-C₂₅ substituents may be connected to each other to form a single substituent having two bonds to the boron atom. Preferably, the C₃-C₂₅ substituents are connected by a single bond or by a difunctional substituent having from one to fifteen non-hydrogen atoms, preferably one to ten. Preferably, a single substituent formed by connecting the first and second C₃-C₂₅ substituents has from twelve to fifty carbon atoms, preferably eighteen to fifty, preferably eighteen to forty. The first and second C₃-C₂₅ substituents may be connected to boron via carbon-boron, nitrogen-boron or oxygen-boron bonds; preferably carbon-boron bonds. Preferably, a C₆-C₂₅ aromatic substituent is not connected to boron via a ring nitrogen atom of an aromatic ring. Preferably, a C₆-C₂₅ aromatic substituent does not contain a pyridine ring, preferably neither a pyridine or a pyrrole ring. The first and second C₃-C₂₅ substituents may contain halogen, nitrogen, oxygen and silicon atoms in addition to hydrogen atoms; preferably no more than ten atoms other than carbon and hydrogen; preferably no more than six. In one preferred embodiment, both C₃-C₂₅ substituents are C₆-C₂₅ aromatic substituents. In one preferred embodiment, one of the C₃-C₂₅ substituents is a C₁-C₆ alkyl group, preferably bonded to the other C₃-C₂₅ substituent as well as to boron. Preferably, the total number of nitrogen and oxygen atoms in the compound of this invention is from two to eight, preferably from three to seven, preferably from three to six. Preferably, the total number of halogen atoms in the compound of this invention is from zero to ten, preferably from zero to six, preferably from zero to four, preferably zero. Preferably halogen atoms are fluorine atoms. Preferably, the total number of silicon atoms in the compound of this invention is from zero to five, preferably from zero to three, preferably from zero to two, preferably zero.

Preferably, a C₆-C₂₅ aromatic substituent has the following structure, where the bond to boron is indicated by a dashed line:

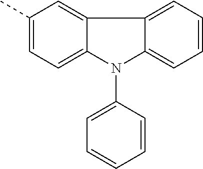

or a similar structure in which one or more aromatic ring carbon atoms may be substituted by C₁-C₄ alkyl groups and/or one or more hydrogen atoms is replaced by deuterium. In a preferred embodiment, the compound comprises two groups having this structure. Preferably, a C₆-C₂₅ aromatic substituent has the following structure, where the bonds to boron are indicated by dashed lines:

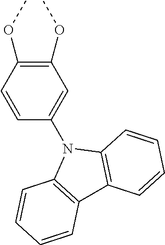

or a similar structure in which one or more aromatic ring carbon atoms may be substituted by C₁-C₄ alkyl groups and/or one or more hydrogen atoms is replaced by deuterium. Preferably, a C₆-C₂₅ aromatic substituent has the following structure, where the bond to boron is indicated by a dashed line:

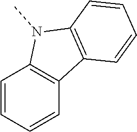

or a similar structure in which one or more aromatic ring carbon atoms may be substituted by C₁-C₄ alkyl groups and/or one or more hydrogen atoms is replaced by deuterium. In a preferred embodiment, the compound comprises two groups having this structure. Preferably, a C₆-C₂₅ aromatic substituent has the following structure, where the bond to boron is indicated by a dashed line:

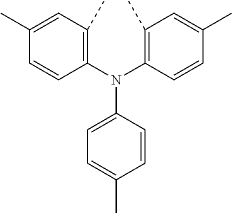

or a similar structure in which one or more aromatic ring carbon atoms may be substituted by C₁-C₄ alkyl groups and/or one or more hydrogen atoms is replaced by deuterium.

Preferably, the bridging substituent has from ten to thirty non-hydrogen atoms. Preferably, the bridging substituent has from five to twenty-five carbon atoms, preferably from seven to twenty carbon atoms. The bridging substituent may contain halogen, nitrogen, oxygen and silicon atoms in addition to carbon and hydrogen or deuterium atoms. Preferably, the bridging substituent has at least one oxygen atom, preferably one which is bonded to the boron atom. Preferably, the bridging substituent has from zero to four nitrogen atoms, preferably one to three. Preferably, the bridging substituent has from zero to four oxygen atoms, preferably one to three, preferably one or two. In one preferred embodiment, the bridging substituent has an oxygen atom bonded to boron and a nitrogen atom bonded to boron. Preferably, one of the bonds to boron in the bridging substituent is a dative bond.

Preferably, the compounds of this invention have formula (I)

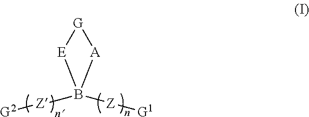

wherein Z and Z′ are NR¹¹ or 0, where R¹¹ is hydrogen or deuterium, a C₆-C₂₅ aromatic substituent, or C₁-C₄ alkyl; n and n′ are 0 or 1; G¹ is the first C₃-C₂₅ substituent and G² is the second C₃-C₂₅ substituent; E is oxygen, nitrogen, sulfur or phosphorus; A is oxygen, nitrogen, sulfur or carbon; and G represents from five to forty atoms connecting E and A and forming at least one aromatic ring wherein G may include a substituent on E or A.

Preferably, the compounds of this invention have formula (II)

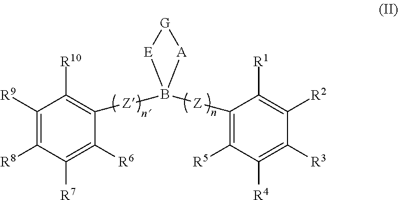

wherein Z and Z′ are NR¹¹ or 0, where R¹¹ is hydrogen or deuterium, a C₆-C₂₅ aromatic substituent or C₁-C₄ alkyl; n and n′ are 0 or 1; R¹, R⁵, R⁶ and R¹⁰ are (i) hydrogen or deuterium, (ii) C₁-C₄ alkyl, (iii) one of R¹ and R⁵ joins with one of R⁶ and R¹⁰ to form a difunctional C₁-C₁₅ substituent which may include at least one nitrogen atom or silicon atom and which connects two aromatic rings, or (iv) one of R¹ and R⁵ and one of R⁶ and R¹⁰ joins with an R group on an adjacent ring carbon to form a C₅-C₇ fused ring; R², R⁴, R⁷ and R⁹ are hydrogen or deuterium, C₁-C₄ alkyl or R², R⁴, R⁷ or R⁹ joins with other R groups as indicated; R³ is: (i) hydrogen or deuterium, (ii) C₁-C₄ alkyl, (iii) a C₆-C₂₀ aromatic substituent attached through a nitrogen atom, or (iv) R³ and one of R² and R⁴ join to form a C₆-C₂₀ aromatic substituent attached through a nitrogen atom and a carbon atom; R⁸ is: (i) hydrogen or deuterium, (ii) C₁-C₄ alkyl, (iii) a C₆-C₂₀ aromatic substituent attached through a nitrogen atom, or (iv) R⁸ and one of R⁷ and R⁹ join to form a C₆-C₂₀ aromatic substituent attached through a nitrogen atom and a carbon atom; E is oxygen, nitrogen, sulfur or phosphorus; A is oxygen, nitrogen, sulfur or carbon; and G represents from five to forty atoms connecting E and A and forming at least one aromatic ring wherein G may include a substituent attached to E or A.

Preferably, R¹¹ is hydrogen or deuterium, a C₆-C₁₅ aromatic substituent, or C₁-C₄ alkyl; preferably a C₆-C₁₅ aromatic substituent or C₁-C₄ alkyl. Preferably, n and n′ are zero, i.e., Z and Z′ are absent. Preferably, R³ and R⁸ are: a C₁₀-C₁₅ aromatic substituent attached through a nitrogen atom, or R³ and one of R² and R⁴ join to form a C₁₀-C₁₅ aromatic substituent attached through a nitrogen atom and a carbon atom. Preferably, one of E and A is oxygen. Preferably, one of E and A is oxygen and the other is nitrogen. Preferably, E is nitrogen and A is oxygen or carbon. Preferably, G represents from eight to eighteen non-hydrogen atoms.

Preferred structures for -E-G-A- include, e.g., with bonds to boron indicated by a dashed line:

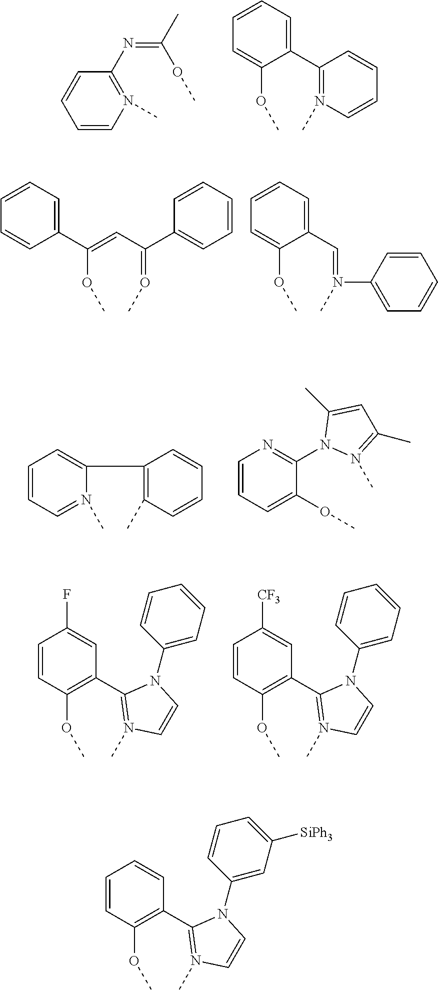

In one preferred embodiment, the compounds of formula (I) are described by formula (III)

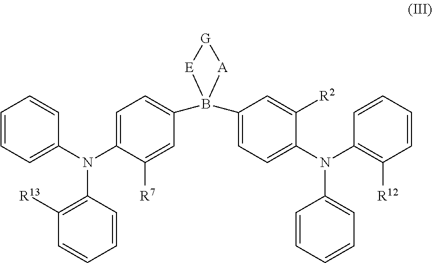

wherein R¹² represents hydrogen or deuterium, or R² and R¹² combine to form a single bond connecting two aromatic rings; and R¹³ represents hydrogen or deuterium, or R⁷ and R¹³ combine to form a single bond connecting two aromatic rings.

Preferably, G represents from ten to sixteen non-hydrogen atoms. Preferably, one of E and A is oxygen. Preferably, one of E and A is oxygen and the other is nitrogen. Preferably, E is nitrogen and A is oxygen or carbon.

In one preferred embodiment, the compounds or formula (I) are described by formula (IV)

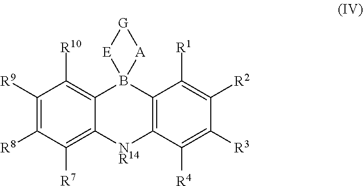

wherein R¹⁴ is a C₆-C₁₅ aromatic substituent.

Preferably, G represents from eight to eighteen non-hydrogen atoms. Preferably, one of E and A is oxygen. Preferably, one of E and A is oxygen and the other is nitrogen. Preferably, E is nitrogen and A is oxygen or carbon. Preferably, R¹⁴ is a C₆-C₁₂ aromatic substituent. Preferably, R¹, R², R³, R⁴, R⁷, R⁸, R⁹ and R¹⁰ are hydrogen or deuterium or C₁-C₄ alkyl; preferably hydrogen or C₁-C₃ alkyl.

The following structures represent preferred embodiments of the invention:

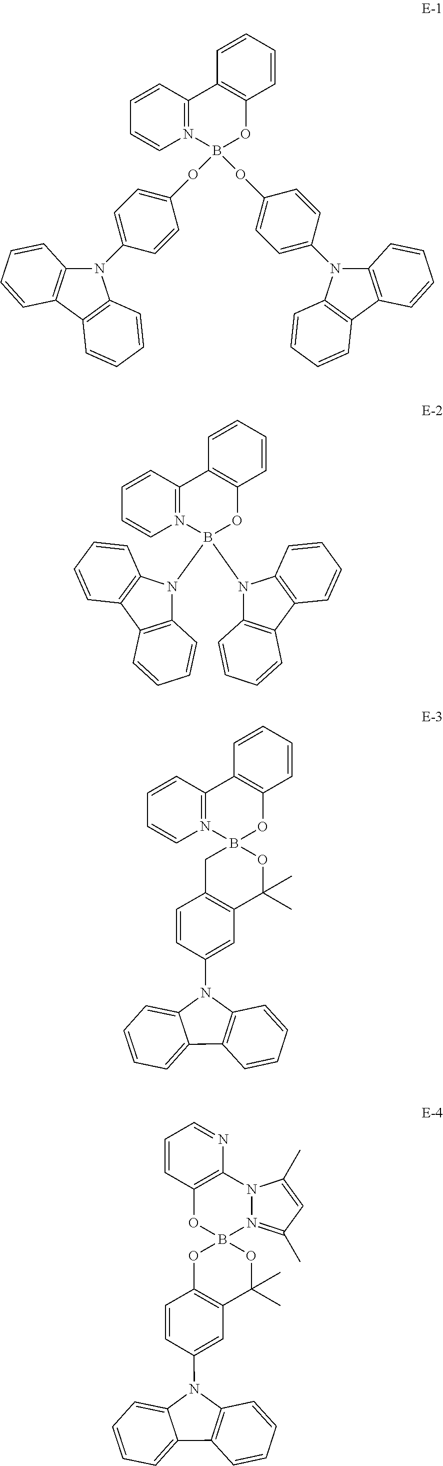

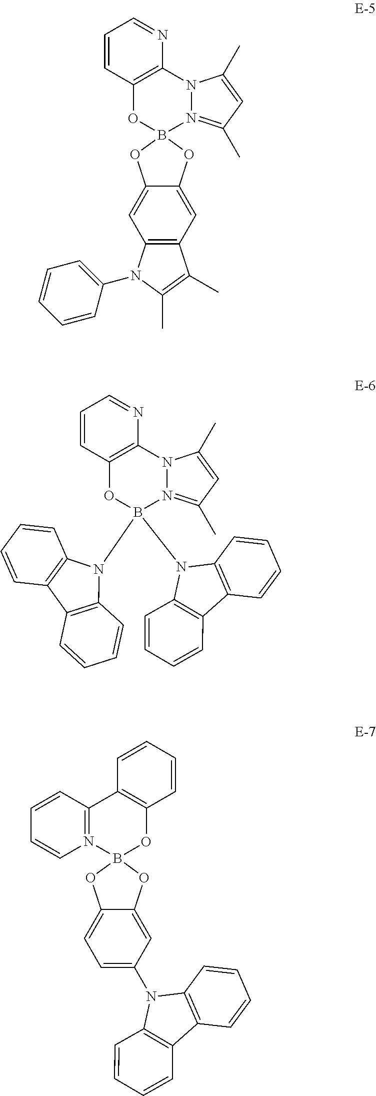

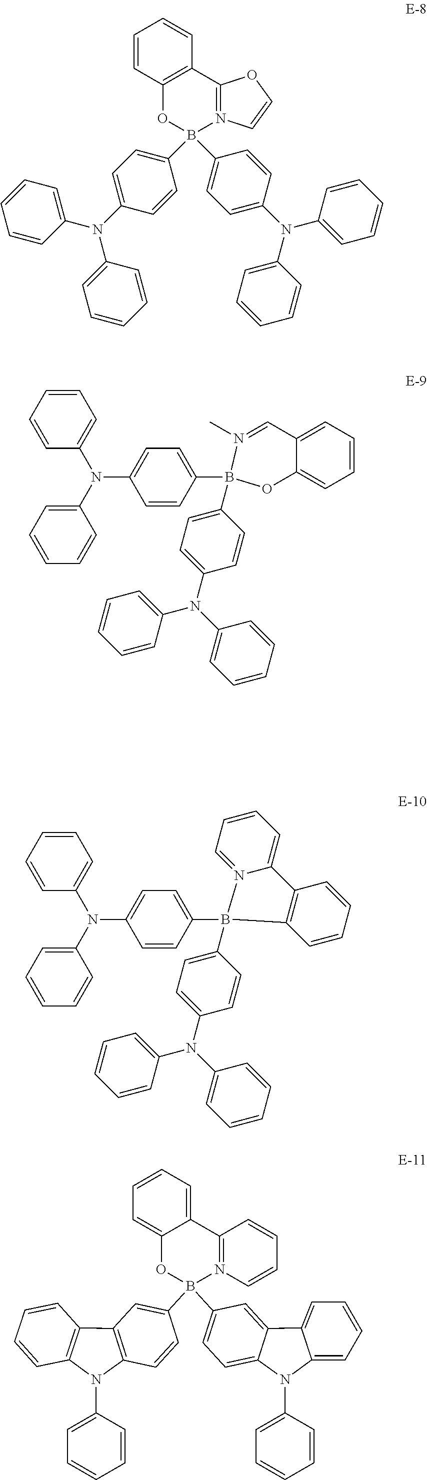

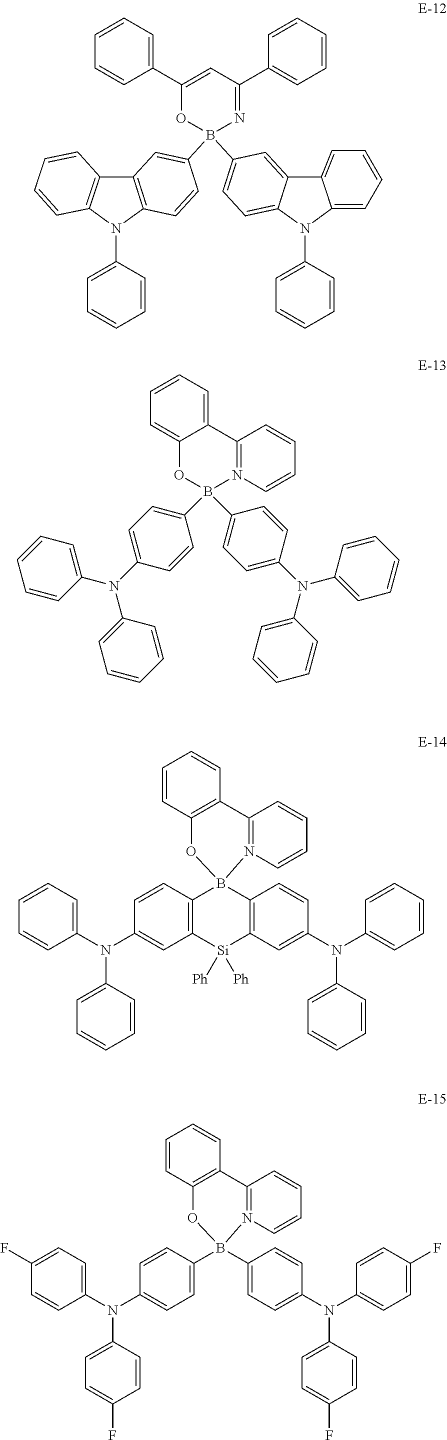

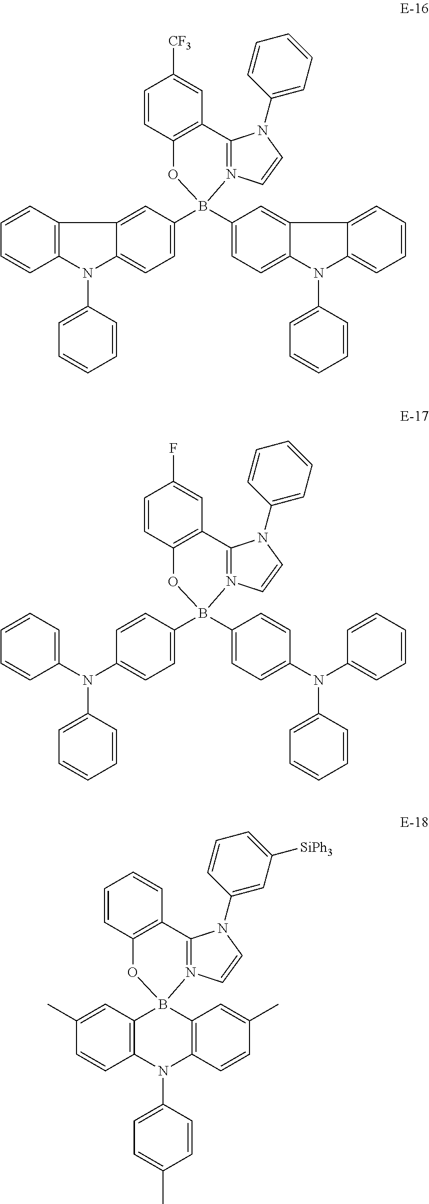

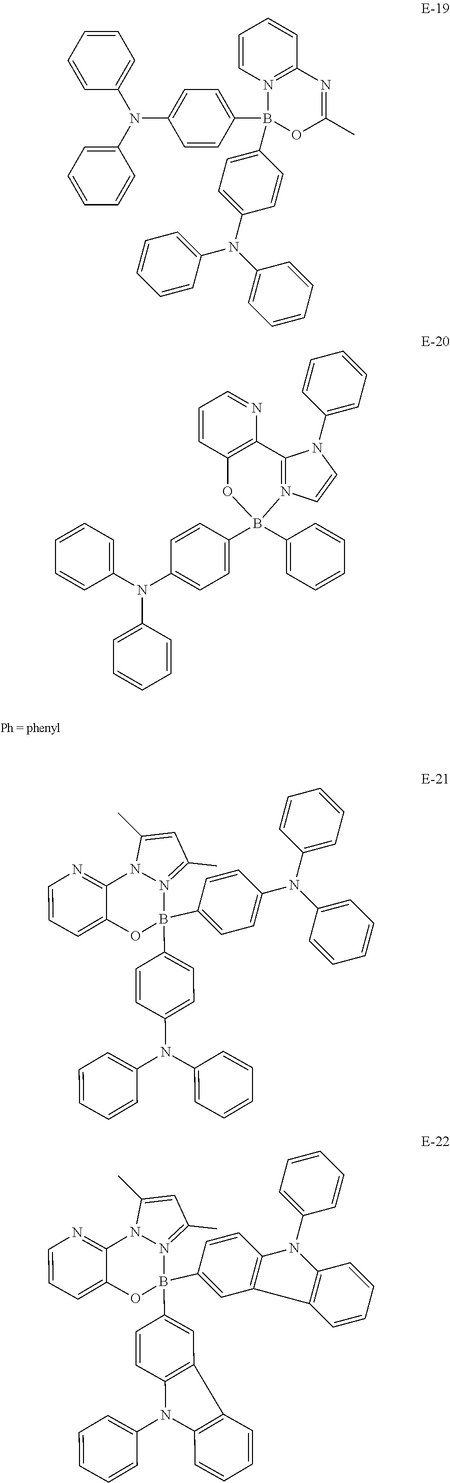

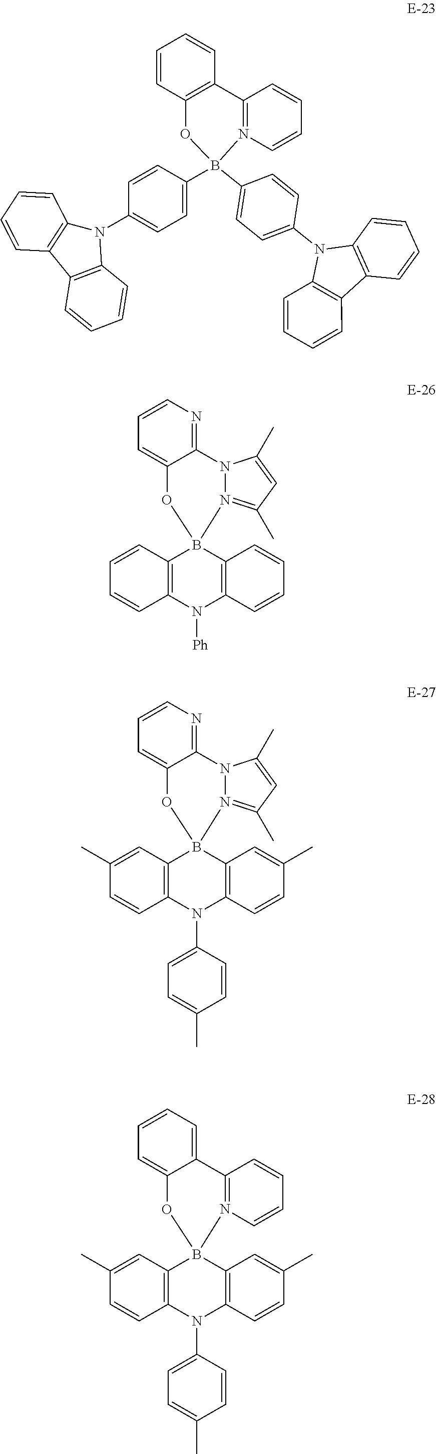

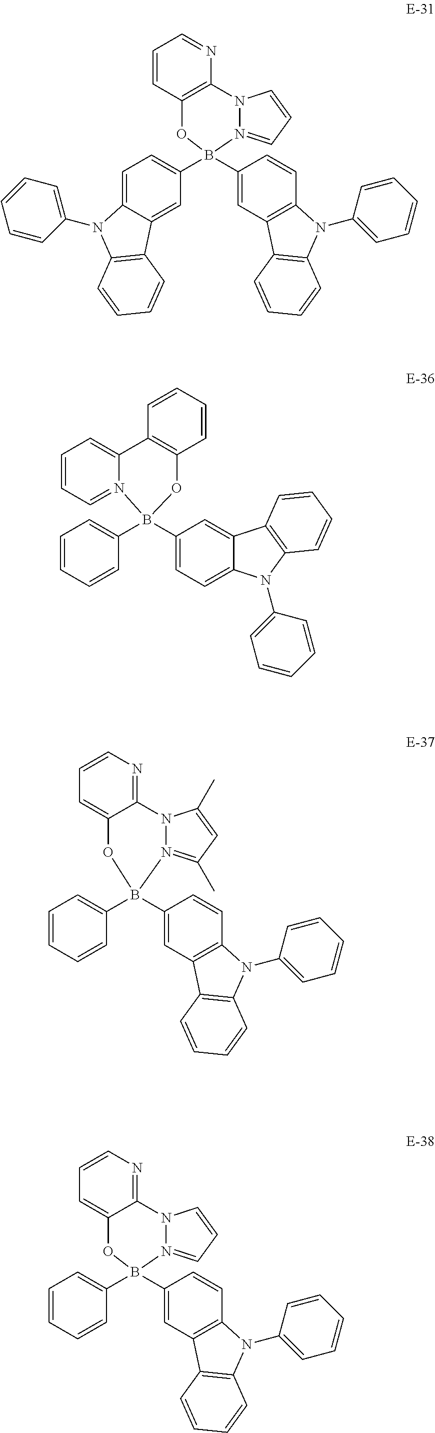

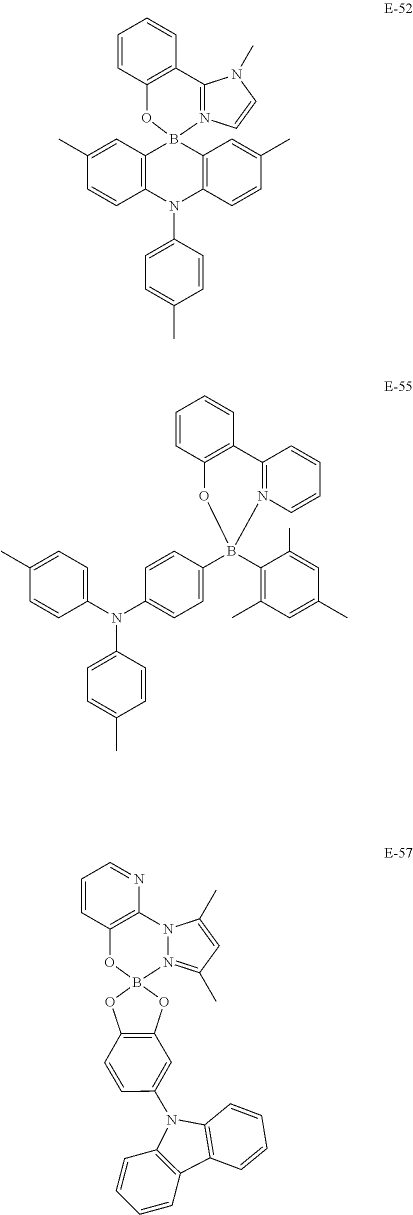

The compounds of this invention may be prepared by methods known in the art, e.g., reaction of aromatic halide compounds with organolithium reagents to form aryllithium compounds followed by combination with trialkyl borates to produce a borinic acid having two aromatic substituents. The borinic acid can be allowed to react with an aromatic compound having at least two nitrogen and/or oxygen atoms having available electrons. Alternately, the borinic acid may be converted to a suitable leaving group such as a borinic ester and reacted with a suitable anion. Otherwise, the compounds of this invention may be prepared by methods known in the art, e.g., reaction of phenolic or amino compounds with trialkyl borate or boron trihalide reagents to form aryl borate or arylaminoboron compounds. The products can be allowed to react with an aromatic compound having at least two nitrogen and/or oxygen atoms having available electrons.

Preferably, at least one compound of this invention is part of an optoelectronic device, e.g., an electroluminescent device, preferably in the emitter layer thereof. Preferably, at least one compound of this invention is used as a thermally activated delayed fluorescent (TADF) dopant, preferably in an OLED device. In some instances, the compound is attached to a polymer which forms a film which can be present in one, some, or all of the following layers: hole injection layer (HIL), a hole transport layer (HTL), an emitting material layer (EML), an electron transport layer (ETL), and an electron injection layer (EIL). Preferably, the film has a layer thickness of at least 5 nm, preferably at least 10 nm, preferably at least 20 nm, preferably no more than 90 nm, preferably no more than 80 nm, preferably no more than 70 nm, preferably no more than 60 nm, preferably no more than 50 nm. In an embodiment, the film is formed with an evaporative process. In an embodiment, the film is formed in a solution process.

Preferably, the electronic device is an OLED device and the present composition is a dopant in the emitting layer. When the present composition is the dopant, the host material has a triplet energy level higher than that of the doped emitter molecule. When the present composition is the dopant, a nonlimiting example of a suitable host material is 9,9′,9″-(pyrimidine-2,4,6-triyl)tris(9H-carbazole). Additional host materials can be found in Yook et al. “Organic Materials for Deep Blue Phosphorescent Organic Light-Emitting Diodes” Adv. Mater. 2012, 24, 3169-3190, and in Mi et al. “Molecular Hosts for Triplet Emitters in Organic Light-Emitting Diodes and the Corresponding Working Principle” Sci. China Chem. 2010, 53, 1679.

Preferably, compound(s) of the present invention are in the emitting layer of the OLED device and are present in a total amount of at least 1 wt %, preferably at least 5 wt %; preferably no more than 25 wt %, preferably no more than 30 wt %, preferably no more than 40.0 wt % based on the total weight of the emitting layer. Additional hosts or dopants can be present in the device or in the emitting layer.

Preferably, the OLED device contains compound(s) of the present invention in the emitting layer and the OLED device emits light by way of TADF. Preferably, the TADF-emitted light is visible light. Preferably, the energy difference between the first triplet state (T1) and the singlet state (S1) is less than 0.7 eV, preferably less than 0.6 eV, preferably less than 0.5 eV. More preferably, the energy difference is less than 0.30 eV. More preferably, the energy difference is less than 0.20 eV. Preferably, the calculated HOMO of the compound is higher than −5.5 eV, preferably higher than −5.3 eV, preferably higher than −5.2 eV, preferably higher than —5.1 eV, preferably higher than −5 eV, preferably higher than −4.9 eV.

### EXAMPLES

### Measurement of Emission Properties:

Emitter-doped polymer films utilized for photoluminescence spectroscopy were prepared by dissolving poly(methyl methacrylate) (PMMA) and the respective emitter in CH₂Cl₂. The PMMA/emitter complex mixtures were filtered through 45 μm PTFE filters and drop cast onto glass microscope coverslips. The resulting films were dried for 15 hours. They were then dried at 60° C., in a vacuum oven, at approximately 1×10⁻² torr (1.33 Pa), for several hours.

Room temperature and 77K spectra reported herein are steady-state emission profiles collected on polymer films inside the sample chamber of a PTI fluorimeter. The profiles were collected using an excitation wavelength of 355 nm. The films were contained in standard borosilicate NMR tubes that were placed into quartz tipped EPR Dewars. Both room temperature and low temperature spectra were acquired in this manner The low temperature spectra were acquired upon filling the Dewar with liquid nitrogen.

Time-resolved emission spectra were acquired on the same samples utilizing the pulsed capabilities of the PTI instrument. The experimental estimate for the S1-T1 gap is obtained by collecting time-resolved emission spectra for doped PMMA films of the inventive composition. Triplet energy level (T1) is defined as the energy difference between the ground state singlet and lowest energy triplet excited state. This value is experimentally estimated by the x-axis intersection point of a tangent line drawn on the high energy side of the delayed component of the emission spectrum taken at 77 Kelvin (K). In cases where time-resolved spectra cannot be measured, the lowest energy peak at 77 Kelvin is used. The singlet energy level (S1) is defined by the energy difference between the ground state singlet energy and the lowest energy singlet excited state. This value is experimentally estimated by the x-axis intersection point of a tangent line drawn on the high energy side of the prompt portion of the emission spectrum at 77 K. The S1-T1 gap is obtained by subtracting the S1 and T1 values.

### Determination of Calculated Values for Complexes:

The ground-state (SO) and first excited triplet-state (T1) configurations of the boron compounds were computed using Density Functional Theory (DFT) at B3LYP/6-31g* level. The energies of highest occupied molecular orbital (HOMO) and lowest unoccupied molecular orbital (LUMO) were obtained from the SO configuration. The energy of the T1 state was computed as the difference in energy between the minima of S0 and T1 potential energy surfaces (PES). The S1-T1 gap was computed as the vertical energy between the S1 and T1 states, at the T1 configuration. The S1-T1 gap was computed using Time Dependent Density Functional Theory (TDDFT). All the calculations were performed using G09 suite of programs (Frisch, M. J. T et al., 02 ed.; Gaussian Inc.: Wallingford Conn., 2009.

| | HOMO | LUMO | T1 | S1 − T1 Gap |
|---|---|---|---|---|
| EM | (eV) | (eV) | (eV) | (eV) |
| I-B-6 | −5.16 | −1.77 | 2.25 | 0.89 |
| E-1 | −5.15 | −2.33 | 2.59 | 0.02 |
| E-2 | −5.09 | −2.38 | 2.32 | 0.01 |
| E-3 | −5.02 | −2.05 | 2.57 | 0.04 |
| E-4 | −4.91 | −1.69 | 2.83 | 0.01 |
| E-5 | −4.42 | −1.43 | 2.62 | 0.03 |
| E-6 | −5.14 | −1.69 | 2.89 | 0.01 |
| E-7 | −4.91 | −2.29 | 2.33 | 0.03 |
| E-8 | −4.67 | −1.84 | 2.47 | 0.05 |
| E-9 | −4.69 | −2.09 | 2.16 | 0.08 |
| E-10 | −4.65 | −1.92 | 2.70 | 0.03 |
| E-11 | −4.97 | −1.90 | 2.45 | 0.26 |
| E-12 | −4.87 | −2.54 | 1.89 | 0.01 |
| E-13 | −4.66 | −2.02 | 2.41 | 0.04 |
| E-14 | −4.69 | −1.94 | 2.37 | 0.08 |
| E-15 | −4.79 | −2.12 | 2.43 | 0.05 |
| E-16 | −4.90 | −1.49 | 2.62 | 0.30 |
| E-17 | −4.59 | −1.53 | 2.43 | 0.21 |
| E-18 | −4.22 | −1.24 | 2.47 | 0.03 |
| E-19 | −4.74 | −1.85 | 2.76 | 0.01 |
| E-20 | −4.60 | −1.57 | 2.49 | 0.10 |
| E-21 | −4.69 | −1.39 | 2.87 | 0.15 |
| E-22 | −5.07 | −1.44 | 2.90 | 0.55 |
| E-23 | −5.12 | −2.23 | 2.48 | 0.20 |
| E-26 | −4.65 | −1.23 | 2.84 | 0.10 |
| E-27 | −4.46 | −1.19 | 2.79 | 0.07 |
| E-28 | −4.44 | −1.81 | 2.26 | 0.04 |
| E-31 | −5.03 | −1.52 | 2.84 | 0.32 |
| E-36 | −5.05 | −1.93 | 2.47 | 0.34 |
| E-37 | −5.00 | −1.32 | 2.89 | 0.49 |
| E-38 | −5.03 | −1.56 | 2.86 | 0.37 |
| E-52 | −4.28 | −1.14 | 2.60 | 0.01 |
| E-55 | −4.52 | −1.98 | 2.33 | 0.04 |
| E-57 | −4.91 | −1.69 | 2.82 | 0.01 |

Values are calculated using Density Functional Theory (DFT) at B3LYP/6-31g* level.

### COMPARATIVE EXAMPLES

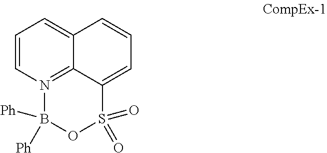

Triphenylborane (0.71 g, 2.9 mmol) was weighed into a glass jar and dissolved in 30 mL toluene. While stirring with a PTFE-coated stirbar, 8-quinolinesulfonic acid (0.61 g, 2.9 mmol) was added to the stirring solution as a solid. The resulting mixture was lightly capped with a PTFE-lined cap and the mixture was placed in an aluminum heating block. The block temperature was increased to 100° C. and the reaction solution was stirred overnight. The resulting mixture was cooled to room temperature. The solid was isolated by filtration through a 20 micron polyethylene frit. The solid was rinsed with hexanes and dried under vacuum: 0.98 g of a white solid (90% yield). ¹H NMR (500 MHz, CD₂Cl₂): δ 8.80 (dd, J=8.4, 1.6 Hz, 1H), 8.73 (dd, J=5.4, 1.5 Hz, 1H), 8.57 (dd, J=7.3, 1.4 Hz, 1H), 8.33 (dd, J=8.3, 1.4 Hz, 1H), 7.99 (t, J=7.9 Hz, 1H), 7.81 (dd, J=8.3, 5.6 Hz, 1H), 7.28-7.21 (m, 6H), 7.17-7.11 (m, 4H) ppm.

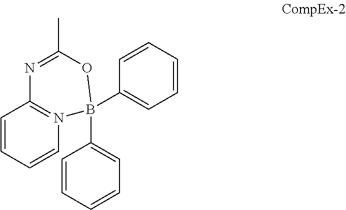

Triphenylborane (0.44 g, 1.8 mmol) was added to a glass jar. The material was dissolved in toluene (20 mL) and the resulting solution was stirred with a PTFE-coated stirbar. The 2-acetamidopyridine (0.25 g, 1.8 mmol) was added as a solid while the reaction mixture was stirring. The reaction mixture was placed in an aluminum heating block and the block temperature was raised to 100° C. while stirring the sample. After stirring for 15 hours at 100° C., the mixture was cooled to room temperature. Hexanes was added to the solution: no solid was formed. The solvent was removed in vacuo. The resulting tacky solid was analyzed by 1H NMR spectroscopy with CD₂Cl₂. The solid was dissolved in 10 mL toluene and hexanes was added. No solid was formed. All but 10 mL of solvent was removed in vacuo. The resulting mixture was placed in a freezer at −40° C. The resulting solid was diluted with hexanes and filtered. The resulting fluffy, white solid (0.15 g) was isolated in 27% yield. ¹H NMR (400 MHz, CD₂Cl₂): δ 7.94-7.83 (m, 2H), 7.38-7.26 (m, 10H), 7.25 (dt, J=8.2, 1.1 Hz, 1H), 7.13 (ddd, J=7.4, 6.1, 1.4 Hz, 1H), 2.33 (s, 3H) ppm. ¹³C NMR (101 MHz, CD₂Cl₂): δ 174.7, 154.9, 147.7 (br), 143.2, 141.6, 133.2, 128.0, 127.4, 122.6, 120.3, 24.5 ppm. ¹¹B NMR (160 MHz, CD₂Cl₂): δ 4.6 ppm.

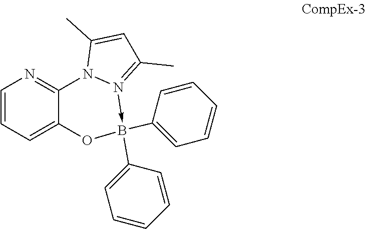 [SMILES: Cc1cc(C)[n+]2n1-c1ncccc1O[B-]2(c1ccccc1)c1ccccc1]

Triphenylborane (0.80 g, 3.3 mmol) was weighed into a glass jar and dissolved in 30 mL toluene. While stirring with a PTFE-coated stirbar, 2-(3,5-dimethyl-1H-pyrazol-1-yl)pyridin-3-ol (0.62 g, 3.3 mmol) was added as a solid. The resulting solution was placed in an aluminum heating block and the block temperature was increased to 100° C. The solution was stirred for 15 hours with a cap loosely placed on the solution. The resulting solution was cooled to room temperature. About 5 mL of solvent was removed in vacuo and the solution was combined with 80 mL hexanes. The resulting white solid was isolated by filtration through a 20 micron polyethylene frit. The solid was dried under vacuum at 60° C. for 30 minutes to yield 0.71 g (61% yield) of the desired product. The product was characterized by ¹H, APT, ¹³C, and ¹¹B NMR spectroscopy in CD₂Cl₂. ¹H NMR (500 MHz, CD₂Cl₂): δ 7.83 (dd, J=4.7, 1.5 Hz, 1H), 7.46-7.40 (m, 1H), 7.26-7.16 (m, 10H), 7.13 (dd, J=8.0, 4.6 Hz, 1H), 6.23 (s, 1H), 2.86 (s, 3H), 1.75 (s, 3H). ppm. ¹³C NMR (126 MHz, CD₂Cl₂): δ 148.1 (C), 147.1 (C), 143.9 (C), 140.9 (C), 137.6 (CH), 133.8 (CH), 128.5 (CH), 127.8 (CH), 127.1 (CH), 124.4 (CH), 111.4 (CH), 16.2 (CH₃), 14.4 (CH3) ppm. ¹¹B NMR (160 MHz, CD₂Cl₂): δ 4.9 ppm.

### Synthesis of Bis(4-diphenylaminophenyl)borinic Acid (A1)

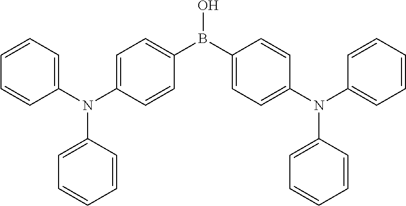 [SMILES: OB(c1ccc(N(c2ccccc2)c2ccccc2)cc1)c1ccc(N(c2ccccc2)c2ccccc2)cc1]

The reactions were set up and run in a nitrogen-purged glovebox, unless otherwise noted. The 4-bromotriphenylamine (7.0 g, Aldrich) was dissolved in 60 mL diethyl ether and cooled in a freezer set to −40° C. The suspension was removed from the freezer and n-butyllithium (9.1 mL of a 2.5M solution in hexanes, Aldrich) was slowly added. The resulting mixture was stirred for 2 hours as the temperature was allowed to rise to room temperature. The resulting mixture was placed in a freezer at −40° C. In a separate jar, triisopropyl borate (2.5 mL, Aldrich) was dissolved in 30 mL diethyl ether and the resulting solution was placed in the freezer. After 15 minutes, both mixtures were removed and the ArLi suspension was slowly added to the borate solution. The resulting mixture was stirred overnight. The mixture was removed from the glovebox and the mixture was quenched with 1M HCl. Solid was present in the bilayer. The yellow organic solution was dried over Na₂SO₄, filtered, and solvent was removed in vacuo in the glovebox. The solid was suspended in a 1:1 mixture of ethyl acetate and methylene chloride. Considerable solid remained. The solid was isolated by filtration and dried under vacuum. The mixture was placed back under vacuum for 1 hour: 1.6 g of a white solid. The product was analyzed by reverse phase LC-MS. Chemical Formula (M+H): C₃₆H₃₀BN₂O, calculated m/z: 517.25, measured: 517.289

### Synthesis of bis(9-phenylcarbazol-3-yl)borinic acid (A2)

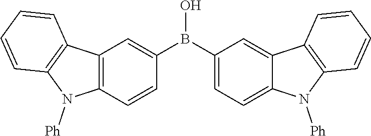 [SMILES: OB(c1ccc2c(c1)c1ccccc1n2-c1ccccc1)c1ccc2c(c1)c1ccccc1n2-c1ccccc1]

The reactions were set up and run in a nitrogen-purged glovebox, unless otherwise noted. The 3-bromo-N-phenylcarbazole (2.5 g) was dissolved in 40 mL diethyl ether and cooled in a freezer set to −40° C. The solution was removed from the freezer and n-butyllithium (3.2 mL of a 2.5M solution in hexanes) was slowly added. The resulting mixture was stirred for 2 hours as the temperature was allowed to rise to room temperature. The resulting mixture was placed in a freezer at −40° C. In a separate jar, triisopropyl borate (0.89 mL) was dissolved in 20 mL diethyl ether and the resulting solution was placed in the freezer. After 15 minutes, both mixtures were removed and the ArLi suspension was slowly added to the borate solution. The resulting mixture was stirred overnight. Half of the reaction mixture was worked up as follows: The mixture was removed from the glovebox and the mixture was quenched with aqueous 1M HCl. The resulting yellow organic solution was separated and dried over Na₂SO₄. The resulting mixture was filtered and solvent was removed in vacuo in the glovebox to yield a solid (0.7 g). The solid was dissolved in a 1:1 mixture of hexanes/CH₂Cl₂ and purified by flash chromatography on silica using a gradient of hexanes and ethyl acetate. The column fractions containing the desired product were placed under vacuum for 2 hours: 0.37 g. The product was characterized by reverse phase LC-MS. Chemical Formula (M+H): C₃₆H₂₆BN₂O Calculated m/z: 513.21, Measured: 513.231

### Synthesis of Bonnie Acid A3

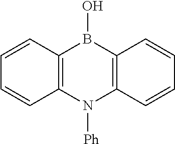 [SMILES: OB1c2ccccc2N(c2ccccc2)c2ccccc21]

The reactions were set up and run in a nitrogen-purged glovebox, unless otherwise noted. A mixture of palladium acetate (0.2 g, 0.89 mmol) and tris(tri-tert-butylphosphonium) tetrafluoroborate (0.5 g, 1.8 mmol) was added to a toluene solution of 2-aniline (2.2 mL) followed by 2-bromoiodobenzene (7.2 mL). Sodium t-butoxide (6.4 g, 67 mmol) was added to the mixture. The mixture was capped and stirred for eight hours in an aluminum block heated to 108° C. A mixture of tris(dibenzylideneacetone)dipalladium (0.2 g) and bis(diphenylphosphino)ferrocene (0.25 g) suspended in toluene was added to the mixture at 108° C. An immediate reaction was noted and t-butanol was formed. 2-bromodiphenylamine was formed as identified by GC-MS. A mixture of palladium acetate (0.1 g, 0.45 mmol) and tris(tri-tert-butylphosphonium) tetrafluoroborate (0.25 g, 0.9 mmol) dissolved in toluene was added and the mixture was stirred for 6 hours at 108° C. The mixture was cooled to room temperature, removed from the glovebox, and extracted with water. The organic layer was isolated and dried over Na₂SO₄. After filtration, solvent was removed in vacuo to leave behind a dark oil. The oil was purified on an ISCO Combiflash on a 220 g silica column using a gradient from pure hexanes to 10:1 hexanes/ethyl acetate. The intermediate 2,2′-dibromotriphenylamine was isolated (1.36 g) by rinsing with hexanes. ¹H NMR (500 MHz, CDCl₃): δ 7.58 (dd, J=8.0, 1.5 Hz, 2H), 7.19 (dtd, J=13.0, 7.3, 1.6 Hz, 4H), 7.10 (dd, J=8.0, 1.6 Hz, 2H), 7.00 (td, J=7.6, 1.6 Hz, 2H), 6.92 (tt, J=7.3, 1.2 Hz, 1H), 6.73-6.65 (m, 2H) ppm. ¹³C NMR (126 MHz, CD₂Cl₂): δ 147.5 (C), 145.6 (C), 134.7 (CH), 129.6 (CH), 129.1 (CH), 128.5 (CH), 126.5 (CH), 122.1 (C), 121.8 (CH), 121.0 (CH) ppm. The 2,2′-dibromotriphenylamine (1.36 g, 3.4 mmol) was dissolved in 30 mL diethyl ether and cooled in a freezer set to −40° C. The solution was removed from the freezer and n-butyllithium (2.8 mL of a 2.5M solution in hexanes) was slowly added. The resulting mixture was stirred for 2 hours as the temperature was allowed to rise to room temperature. The resulting mixture was placed in a freezer at −40° C. Triisopropyl borate (0.75 mL, 3.2 mmol) was dissolved in 15 mL diethyl ether and the resulting solution was placed in the freezer. After 15 minutes, both mixtures were removed and the ArLi suspension was slowly added to the borate solution. The resulting mixture was stirred overnight. After removing the reaction mixture from the glovebox, the mixture was quenched with 1M HCl. After stirring the bilayer for about 5 minutes, the two layers were separated. After filtration the yellow organic solution was brought back into the glovebox and solvent was removed in vacuo in the glovebox. The solid was dissolved in methylene chloride and the product was purified by flash chromatography on silica using an ISCO Combiflash using a gradient of hexanes and ethyl acetate as the mobile phase. The resulting product (0.072 g, 8% yield) was analyzed by NMR spectroscopy. The spectra are consistent with the formation of the desired product as the anhydride of the borinic acid with about 14% of the sample being in the form of the borinic acid. ¹H NMR (500 MHz, CD₂Cl₂) δ 8.16 (dd, J=7.6, 1.7 Hz, 1H), 7.76 (t, J=7.7 Hz, 1H), 7.67 (t, J=7.4 Hz, 1H), 7.49-7.40 (m, 2H), 7.06 (t, J=7.2 Hz, 1H), 6.78 (d, J=8.7 Hz, 1H). ¹³C NMR (126 MHz, CD₂Cl₂): δ 150.3, 142.4, 133.1, 132.5, 131.6, 131.2, 129.3, 121.0, 117.3 ppm.

### Synthesis of Bonnie Acid A4

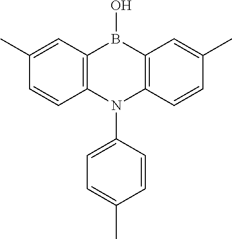

Tri-p-tolylamine (4.5 g, 15 mmol from Alfa Aesar) was dissolved in 60 mL chloroform. In a separate jar, N-bromosuccinimide (5.7 g, 32 mmol) was dissolved in 40 mL acetonitrile. At room temperature, the NBS solution was added slowly to the solution of the amine over about 45 minutes. The resulting solution was stirred overnight at room temperature. The solution was poured into water and the organic layer was extracted with additional chloroform. The organic solution was dried over MgSO₄, filtered, and the solvent was removed in vacuo. The mixture was treated with 15 mL methanol and a white solid precipitated out of the solution. The methanol solution was decanted and the solid was rinsed with methanol and dried under vacuum to leave behind a white solid. The material was dried under vacuum at 100° C. to remove residual methanol. The 2,2′-dibromo-4,4′,4″-trimethyltriphenylamine (4.7 g) was isolated in 67% yield.

The 2,2′-dibromo-4,4′,4″-trimethyltriphenylamine (6.0 g, 13 mmol) was dissolved in 60 mL diethyl ether and cooled in a freezer set to −40° C. The solution was removed from the freezer and n-butyllithium (11.3 mL of a 2.5M solution in hexanes) was slowly added. The resulting mixture was stirred for 2 hours as the temperature was allowed to rise to room temperature. The resulting mixture was placed in a freezer at −40° C. Triisopropyl borate (3.0 mL, 18 mmol) was dissolved in 30 mL diethyl ether and the resulting solution was placed in the freezer. After 15 minutes, both mixtures were removed and the ArLi suspension was slowly added to the borate solution. After about half the ArLi was added, an additional 1.0 mL of triisopropyl borate was added to the reaction mixture. The remainder of the ArLi solution was added. The resulting mixture was stirred overnight. The mixture was quenched with 1M HCl. The resulting organic layer was brought back into the glovebox and solvent was removed in vacuo in the glovebox. The mixture was dissolved in 10 mL methylene chloride and the solution was purified through silica on an ISCO Combiflash using a gradient of hexanes and ethyl acetate. The solid was heated to 60° C. under vacuum for two hours to yield the desired product (0.55 g, 13% yield). The data is consistent with the formation of a mixture of borinic acid and borinic acid anhydride. ¹¹B NMR (160 MHz, CD₂Cl₂): δ 38.7 ppm. Chemical Formula (M+H): C₂₁H₂₀BNO, calculated m/z: 314.101, measured: 314.17

### Synthesis of Bonnie Acid A5

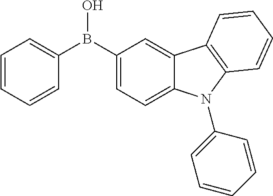 [SMILES: OB(c1ccccc1)c1ccc2c(c1)c1ccccc1n2-c1ccccc1]

The reactions were set up and run in a nitrogen-purged glovebox, unless otherwise noted. The 3-bromo-N-phenylcarbazole (5.0 g, 16 mmol from Alfa Aesar) was dissolved in 60 mL diethyl ether and cooled in a freezer set to −40° C. The solution was removed from the freezer and n-butyllithium (6.5 mL of a 2.5M solution in hexanes) was slowly added. The resulting mixture was stirred for 2 hours as the temperature was allowed to rise to room temperature. The resulting mixture was placed in a freezer at −40° C. In a separate jar, phenylboronic acid pinacol ester (3.1 g, 16 mmol) was dissolved in 20 mL diethyl ether and the resulting solution was placed in the freezer. After 15 minutes, both mixtures were removed and the ArLi suspension was slowly added to the boronic ester solution. The resulting mixture was stirred at room temperature for 3 hours. The resulting mixture was removed from the glovebox and quenched with 1M HCl. The resulting yellow organic solution was brought back into the glovebox and solvent was removed in vacuo in the glovebox. Once only about 30 mL cold ether was present, a white solid was present. The solid was filtered and removed. The remaining solution was placed under vacuum to remove all solvent. The oil was dissolved in 15 mL methylene chloride and purified by flash chromatography on silica gel using an ISCO Combiflash and a hexanes/ethyl acetate gradient as the solvent. The product (2.9 g) was isolated in 54% yield as a mixture of borinic acid and borinic acid anhydride. “B NMR (160 MHz, CD₂Cl₂): δ 45.1 ppm. Chemical Formula (M+H): C₂₄H₁₉BNO, calculated m/z: 348.16, measured: 348.07

### Synthesis of Bonnie Acid A6

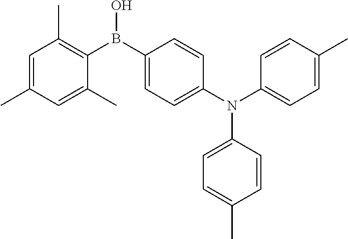

The reactions were set up and run in a nitrogen-purged glovebox. 4-Bromo-4′,4″-dimethyltriphenylamine (6.0 g, 17 mmol from eNovation Chemicals) was dissolved in 60 mL diethyl ether and cooled in a freezer set to −40° C. The solution was removed from the freezer and n-butyllithium (7.2 mL of a 2.5M solution in hexanes) was slowly added. The resulting mixture was stirred for four hours as the temperature was allowed to rise to room temperature. The resulting mixture was placed in a freezer at −40° C. In a separate jar, 2,4,6-trimethylphenylboronic acid pinacol ester (4.6 g, 19 mmol from AKSci) was dissolved in 30 mL diethyl ether. After cooling the second solution in the freezer, the aryllithium suspension was slowly added to the boronic ester solution. The resulting mixture was stirred overnight at room temperature. The resulting mixture was removed from the glovebox and poured into 1M HCl. After mixing for about 5 minutes, the resulting yellow organic layer was isolated and brought back into the glovebox. Solvent was removed in vacuo and the residue was purified by flash chromatography using a gradient of hexanes and ethyl acetate on an ISCO Combiflash. Solvent was removed in vacuo from the product to yield 3.6 g (50% yield). ¹H NMR (500 MHz, CD₂Cl₂): δ 7.52-7.45 (m, 2H), 7.11 (d, J=8.1 Hz, 4H), 7.02 (d, J=8.1 Hz, 4H), 6.89-6.85 (m, 2H), 6.83 (s, 2H), 5.70 (s, 1H), 2.32 (s, 6H), 2.28 (s, 3H), 2.19 (s, 6H). ppm. ¹³C NMR (126 MHz, CD₂Cl₂): δ 152.0, 145.1, 139.5, 138.2, 136.9, 134.4, 130.6, 127.6, 126.3, 119.7, 22.4, 21.5, 21.2 ppm. ¹¹B NMR (160 MHz, CD₂Cl₂): δ 47.5 ppm.

### Synthesis of 2-(1H-pyrazol-1-yl)pyridin-3-ol

2-Bromo-3-hydroxypyridine (5.0 g, 29 mmol from Alfa Aesar) was combined with copper iodide (0.55 g, 2.9 mmol) and potassium carbonate (8 g, 57 mmol). The mixture was suspended in acetonitrile (80 mL) and DMEDA (0.77 mL, 7.2 mmol) was added while stirring the mixture with a PTFE-coated stirbar. Pyrazole (2.3 g, 34 mmol from Acros) was added. The resulting mixture was capped and placed in an aluminum block heated to 80° C. The resulting mixture was stirred for 15 hours at 80° C. After cooling to room temperature, solvent was removed in vacuo. The residue was suspended in 50 mL methylene chloride and removed from the glovebox. The mixture was treated with 50 mL water. The organic layer was isolated and dried over MgSO₄. After filtration, solvent was removed in vacuo. The resulting material was purified by flash chromatography on silica gel using an ISCO Combiflash and a 20:1 hexanes/ethyl acetate mixture as the solvent. The product (2.4 g) was isolated in 52% yield. ¹H NMR (500 MHz, Chloroform-d) δ 11.73 (s, 1H), 8.63 (dd, J=2.6, 0.8 Hz, 1H), 7.94 (dd, J=4.6, 1.5 Hz, 1H), 7.73 (dd, J=1.9, 0.8 Hz, 1H), 7.39 (dd, J=8.1, 1.5 Hz, 1H), 7.16-7.09 (m, 1H), 6.51 (dd, J=2.7, 1.9 Hz, 1H). ¹³C NMR (126 MHz, CD₂Cl₂): δ 149.9, 145.1, 139.5, 138.3, 127.5, 126.5, 123.1, 106.8 ppm.

### Synthesis of 2-(3,5-dimethyl-1H-pyrazol-1-yl)pyridin-3-ol

2-Bromo-3-hydroxypyridine (5.0 g, 29 mmol from Alfa Aesar) was combined with copper iodide (0.55 g, 2.9 mmol) and potassium carbonate (7.9 g, 57 mmol). The mixture was suspended in acetonitrile (80 mL) and DMEDA (0.77 mL, 7.2 mmol) was added while stirring the mixture with a PTFE-coated stirbar. 3,5-Dimethylpyrazole (3.3 g, 34 mmol from Alfa Aesar) was added. The resulting mixture was capped and placed in an aluminum block heated to 80° C. The resulting mixture was stirred for 15 hours at 80° C. After cooling to room temperature, the mixture was filtered and solvent was removed in vacuo. The residue was purified by flash chromatography on an ISCO Combiflash using 5% ethyl acetate in hexanes as the solvent. The product peak came through at 2.0 CV at 5% ethyl acetate in hexanes. A white, crystalline product (1.93 g) was isolated in 35% yield. ¹H NMR (500 MHz, CDCl₃) δ 12.10 (s, 1H), 7.90 (dd, J=4.6, 1.5 Hz, 1H), 7.34 (dd, J=8.1, 1.5 Hz, 1H), 7.06 (dd, J=8.0, 4.5 Hz, 1H), 6.00 (s, 1H), 2.72 (s, 3H), 2.30 (s, 3H).

### Synthesis of 1-methyl-2-(2-hydroxyphenyl)imidazoline

The reaction was set up and run in a nitrogen-purged glovebox. The 1-methyl-2-(2-hydroxyphenyl)imidazoline was synthesized by a known procedure similar manner to a published experimental procedure (J. Am. Chem. Soc. 1974, 96, 2464). The 1-methyl-2-(2-hydroxyphenyl)imidazoline (4.1 g, 24 mmol) was added to a glass jar and dissolved in 60 mL m-xylene. While stirring 5.0 g of manganese(IV) oxide (120 mmol) was added. The reaction was heated to 115° C. and stirred for 1 hour. After 1 hour of reaction time, the mixture was filtered. Solvent was removed in vacuo. The resulting residue was removed from the glovebox and dissolved in 2M HCl. The aqueous solution was rinsed with xylenes. The aqueous layer was neutralized with NaHCO₃. The aqueous solution was extraction with chloroform. The chloroform solution was placed under vacuum and volatiles were removed. The residue was purified by flash chromatography on silica using an ISCO Combiflash with hexanes/ethyl acetate as the mobile phase. The desired product was isolated as a white crystalline solid (0.32 g, 7.7% yield). 1H NMR (400 MHz, Chloroform-d) δ 12.87 (s, 1H), 7.53 (dd, J=7.9, 1.6 Hz, 1H), 7.24 (ddd, J=8.2, 7.3, 1.6 Hz, 1H), 7.10-7.03 (m, 2H), 6.91-6.82 (m, 2H), 3.87 (s, 3H). 13C NMR (101 MHz, cdcl3) δ 157.87, 145.69, 130.03, 125.43, 125.36, 122.76, 118.41, 117.76, 113.90, 36.29.

### General Procedure

The reactions are set up and run in a nitrogen-purged glovebox. Combine borinic acid with methylene chloride and add the protonated chelating ligand. Allow mixture to stir for 3 hours to 15 hours. Remove solvent under vacuum. Recrystallize product from a 10:1 mixture of hexanes to methylene chloride.

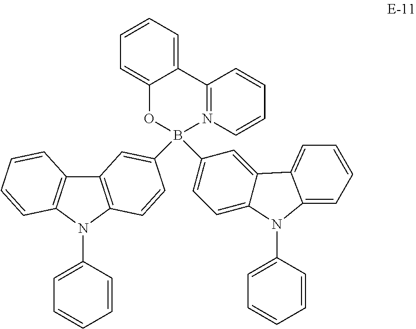

General Procedure A was followed with the following changes: The borinic acid A2 (2.0 g) was dissolved in 50 mL methylene chloride and stirred with a PTFE-coated stirbar. While stirring, the 2-(2-hydroxyphenyl)pyridine (0.66 g) was added as a solid. The resulting yellow solution was stirred for 3 hours at room temperature.

The product was isolated in 70% yield (1.78 g). ¹H NMR (500 MHz, CD₂Cl₂): δ 8.35 (ddd, J=6.0, 1.6, 0.8 Hz, 1H), 8.10-7.98 (m, 6H), 7.71 (dd, J=8.0, 1.6 Hz, 1H), 7.64-7.56 (m, 7H), 7.49-7.38 (m, 6H), 7.41-7.30 (m, 6H), 7.27 (dd, J=8.3, 1.2 Hz, 1H), 7.22-7.15 (m, 2H), 6.87 (ddd, J=8.2, 7.2, 1.2 Hz, 1H). ppm. ¹³C NMR (126 MHz, CD₂Cl₂): δ 161.0 (C), 151.4 (C), 144.9 (CH), 141.5 (CH), 141.3 (C), 140.9 (C), 138.7 (C), 134.7 (CH), 132.2 (CH), 130.3 (CH), 127.6 (CH), 127.5 (CH), 126.1 (CH), 125.8 (CH), 125.6 (CH), 124.3 (C), 123.4 (C), 122.7 (CH), 121.6 (CH), 121.5 (CH), 120.6 (CH), 120.1 (CH), 119.5 (C), 110.0 (CH), 109.2 (CH) ppm. ¹¹B NMR (160 MHz, CD₂C1₂): δ 6.2 ppm.

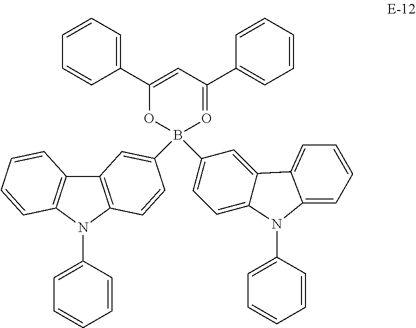

General Procedure A was followed with the following changes: the borinic acid A2 (0.18 g, 0.35 mmol) was dissolved in 5 mL methylene chloride and stirred with a PTFE-coated stirbar. While stirring, 1,3-diphenyl-1,3-propanedione (0.070 g, 0.31 mmol) was added as a solid. The resulting solution was stirred for 3 hours at room temperature.

The product (0.14 g) was isolated in 61% yield. ¹H NMR (500 MHz, CD₂Cl₂): δ 8.43 (t, J=1.0 Hz, 2H), 8.35-8.29 (m, 4H), 8.09 (dt, J=7.8, 1.0 Hz, 2H), 7.77-7.69 (m, 4H), 7.67-7.54 (m, 11H), 7.49-7.40 (m, 2H), 7.42-7.30 (m, 6H), 7.23-7.18 (m, 2H), 7.16 (s, 1H) ppm. ¹³C NMR (126 MHz, CD₂Cl₂): δ 183.7 (C), 141.3 (C), 141.0 (C), 138.6 (C), 135.1 (CH), 134.1 (C), 130.6 (CH), 130.3 (CH), 129.7(CH), 129.2 (CH), 127.6 (CH), 127.5 (CH), 125.8 (CH), 124.4 (C), 123.7 (CH), 123.3 (C), 120.6 (CH), 120.0 (CH), 110.0 (CH), 109.3 (CH), 95.0 (CH) ppm.

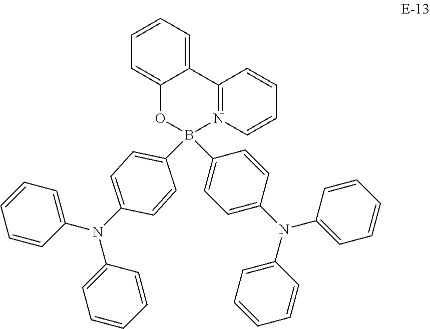

General Procedure A was followed with the following changes: The borinic acid A1 (0.30 g, 0.35 mmol) was weighed into a 20 mL glass vial with a PTFE-coated stirbar. The solid was suspended in methylene chloride (10 mL). While stirring the reaction mixture, solid 2-(2-hydroxyphenyl)pyridine (0.10 g, 0.35 mmol) was added.

The product (0.27 g) was isolated in 69% yield. ¹H NMR (500 MHz, CD₂Cl₂): δ 8.24 (ddd, J=6.0, 1.7, 0.8 Hz, 1H), 8.09-7.99 (m, 2H), 7.74 (dd, J=8.0, 1.6 Hz, 1H), 7.46-7.37 (m, 2H), 7.25-7.17 (m, 8H), 7.21-7.11 (m, 5H), 7.09-7.00 (m, 8H), 7.00-6.89 (m, 9H) ppm. ¹³C NMR (126 MHz, CD₂Cl₂): δ 160.6, 151.2, 148.7, 146.7, 144.6, 143.4 (br), 141.5, 134.7, 134.6, 129.6, 126.1, 124.4, 123.9, 122.8, 121.5, 121.4, 119.8, 119.1 ppm. ¹¹B NMR (160 MHz, CD₂Cl₂): δ 5.3 ppm.

E-13 was characterized by single crystal X-Ray Diffractometry on crystals formed by slow evaporation of a methylene chloride/hexanes solution.

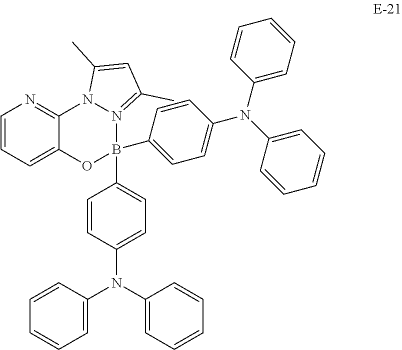

General Procedure A was followed with the following changes: The borinic acid A1 (0.39 g, 0.76 mmol) was dissolved in 30 mL methylene chloride. While stirring the solution, the 2-(3,5-dimethyl-1H-pyrazol-1-yl)pyridin-3-ol (0.14 g, 0.76 mmol) was added as a solid.

The product (0.21 g) was isolated in 40% yield. ¹H NMR (400 MHz, CD₂Cl₂): δ 7.87 (dd, J=4.6, 1.6 Hz, 1H), 7.44 (dd, J=8.1, 1.6 Hz, 1H), 7.30-7.12 (m, 13H), 7.12-6.91 (m, 16H), 6.23 (t, J=0.7 Hz, 1H), 2.85 (s, 3H), 1.87 (s, 3H) ppm. ¹³C NMR (101 MHz, CD₂Cl₂): δ 148.7, 148.0, 147.1, 146.8, 143.8, 142.7 (br), 140.9, 137.5, 134.6, 129.6, 128.6, 124.4, 124.3, 124.1, 122.7, 111.5, 16.2, 14.5 ppm.

The structure was confirmed by single-crystal X-Ray Diffractometry on crystals grown from slow diffusion of a methylene chloride/hexanes bilayer.

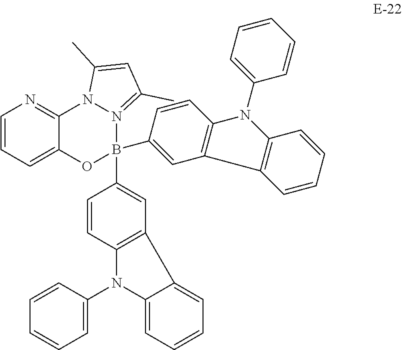

General Procedure A was followed with the following changes: Borinic acid A2 (0.48 g, 0.94 mmol) was dissolved in 30 mL methylene chloride and the solution was stirred with a PTFE-coated stirbar. While stirring, the 2-(3,5-dimethyl-1H-pyrazol-1-yl)pyridin-3-ol (0.18 g, 0.94 mmol) was added as a solid to the solution.

The product (0.50 g) was isolated in 78% yield. ¹H NMR (500 MHz, CD₂C1₂): δ 8.04 (s, 2H), 8.02 (d, J=7.7 Hz, 2H), 7.80 (dd, J=4.6, 1.5 Hz, 1H), 7.60 (d, J=5.1 Hz, 8H), 7.52 (dd, J=8.1, 1.5 Hz, 1H), 7.48-7.42 (m, 2H), 7.42-7.30 (m, 9H), 7.19 (td, J=7.4, 1.0 Hz, 2H), 7.12 (dd, J=8.1, 4.6 Hz, 1H), 2.89 (s, 3H), 1.80 (s, 3H) ppm. ¹³C NMR (101 MHz, CD₂Cl₂): δ 148.3, 147.4, 143.8, 141.3, 141.1, 141.0, 138.6, 137.4, 132.2, 130.3, 128.6, 127.6, 127.4, 125.8, 125.5, 124.4, 123.4, 120.6, 120.0, 111.5, 110.0, 109.2, 16.2, 14.7 ppm.

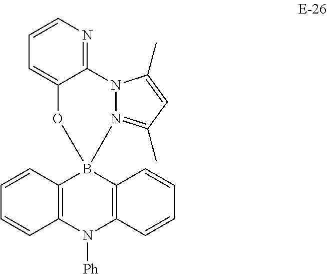

General Procedure A was followed with the following changes: The borinic acid A3 (0.072 g, 0.14 mmol) was dissolved in 10 mL methylene chloride. While stirring with a PTFE-coated stirbar, the pyridinol (0.052 g, 0.27) was added as a solid.

A second recrystallization was done from toluene/hexanes to yield 30 mg (24% yield) of product. ¹H NMR (500 MHz, CD₂Cl₂): δ 7.97 (dd, J=4.5, 1.6 Hz, 1H), 7.69-7.63 (m, 2H), 7.57-7.50 (m, 1H), 7.37 (dd, J=8.1, 1.5 Hz, 1H), 7.34-7.28 (m, 2H), 7.25-7.18 (m, 3H), 7.00 (ddd, J=8.6, 7.0, 1.7 Hz, 2H), 6.73 (td, J=7.2, 1.0 Hz, 2H), 6.25 (dd, J=8.5, 0.9 Hz, 2H), 6.13 (t, J=0.8 Hz, 1H), 2.98 (d, J=0.7 Hz, 3H), 1.64 (s, 3H) ppm. ¹³C NMR (126 MHz, CD₂Cl₂): δ 148.3, 146.9, 145.8, 143.9, 143.6, 139.3, 136.7, 132.9, 132.1, 131.5, 128.4, 128.1, 128.0, 124.7, 119.6, 115.0, 111.6, 16.7, 13.4 ppm.

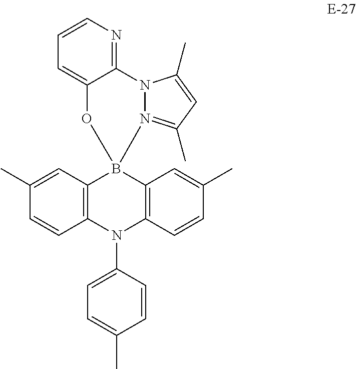

General Procedure A was followed with the following changes: The borinic acid A4 (0.25 g, 0.80 mmol) was dissolved in 10 mL methylene chloride and the solution was stirred with a PTFE-coated stirbar. While stirring, a 5 mL methylene chloride solution of 2-(3,5-dimethyl-1H-pyrazol-1-yl)pyridin-3-ol (0.16 g, 0.88 mmol) was added.

The bulk sample (about 200 mg) was suspended in 6 mL toluene. Solid remained. The solid was isolated by filtration, dissolved in methylene chloride, and dried under vacuum at 70° C. A total of 100 mg (26% yield) of product was isolated, which was characterized by NMR spectroscopy. ¹H NMR (500 MHz, CD₂Cl₂): δ 7.96 (dd, J=4.6, 1.5 Hz, 1H), 7.45-7.40 (m, 2H), 7.36 (dd, J=8.1, 1.6 Hz, 1H), 7.22 (dd, J=8.1, 4.6 Hz, 1H), 7.17-7.12 (m, 2H), 6.98 (d, J=2.2 Hz, 2H), 6.80 (ddd, J=8.6, 2.3, 0.8 Hz, 2H), 6.16 (d, J=8.5 Hz, 2H), 6.13-6.10 (m, 1H), 2.99 (s, 3H), 2.50 (s, 3H), 2.11 (s, 6H), 1.63 (s, 3H). δ ppm. ¹³C NMR (126 MHz, CD₂Cl₂): δ 148.3, 145.8, 145.1, 143.5, 141.6, 139.1, 138.1, 136.5, 133.0, 132.0, 131.7, 128.9, 128.0, 127.9, 124.6, 114.8, 111.6 ppm.

The structure was verified by single-crystal X-Ray Diffractometry of crystals grown by slow evaporation of a methylene chloride/hexanes solution.

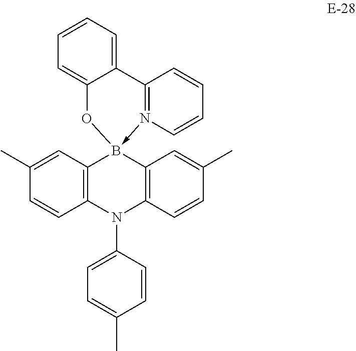

General Procedure A was followed with the following changes: The borinic acid A4 (0.15 g, 0.48 mmol) was weighed into a glass vial with a PTFE-coated stirbar. The solid was dissolved in methylene chloride (8 mL). While stirring the reaction mixture, a methylene chloride solution of 2-(2-hydroxyphenyl)pyridine (0.09 g in 3 mL, 0.53 mmol) was added.

The yellow solid with rinsed with small amounts (about 2-4 mL) of toluene and methylene chloride. The resulting yellow solid (0.08 g, 36% yield) was characterized by NMR spectroscopy. ¹H NMR (500 MHz, CD₂Cl₂): δ 8.09 (d, J=8.2 Hz, 1H), 7.95-7.86 (m, 3H), 7.50-7.41 (m, 3H), 7.24-7.18 (m, 3H), 7.16 (d, J=2.2 Hz, 2H), 7.05-6.96 (m, 2H), 6.79 (dd, J=8.5, 2.3 Hz, 2H), 6.20 (d, J=8.5 Hz, 2H), 2.50 (s, 3H), 2.08 (s, 6H) ppm. ¹³C NMR (126 MHz, CD₂Cl₂): δ 159.8, 150.6, 146.1, 144.7, 141.5, 140.8, 138.1, 135.1, 133.1, 131.9, 131.7, 128.9, 128.2, 126.1, 123.2, 121.2, 120.1, 119.2, 116.9, 114.9, 21.6, 20.8 ppm. ¹¹B NMR (160 MHz, CD₂Cl₂): δ 2.0 ppm.

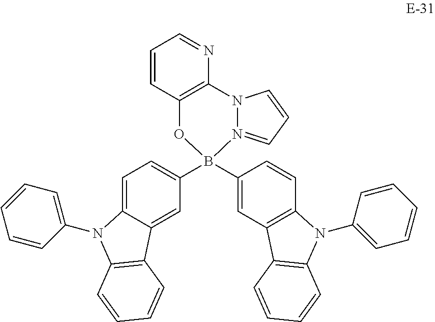

General Procedure A was followed with the following changes: The borinic acid A2 (0.60 g, 1.17 mmol) was dissolved in 30 mL methylene chloride and the solution was stirred with a PTFE-coated stirbar. While stirring, the 2-(pyrazol-1-yl)pyridin-3-ol (0.19 g, 1.23 mmol) was added as a solid to the solution.

Solids were placed under vacuum for over 1 hour at 120° C. to yield 312 mg of product (41% yield). ¹H NMR (500 MHz, CD₂Cl₂): δ 8.72 (dd, J=2.8, 1.0 Hz, 1H), 8.08 (t, J=1.0 Hz, 2H), 8.03 (dt, J=7.8, 1.0 Hz, 2H), 7.85 (dd, J=4.6, 1.5 Hz, 1H), 7.74 (dd, J=2.4, 1.0 Hz, 1H), 7.64 (dd, J=8.2, 1.5 Hz, 1H), 7.63-7.54 (m, 8H), 7.47-7.42 (m, 2H), 7.40 (tt, J=7.0, 1.2 Hz, 4H), 7.37-7.31 (m, 4H), 7.24 (dd, J=8.2, 4.6 Hz, 1H), 7.20 (ddd, J=7.9, 7.0, 1.1 Hz, 2H), 6.77 (t, J=2.6 Hz, 1H) ppm. ‘³C NMR (126MHz, CD₂Cl₂): δ 147.0 (C), 141.3 (C), 141.1 (C), 138.6 (C), 138.4 (CH), 137.7 (CH), 131.7 (CH), 130.3 (CH), 127.7 (CH), 127.5 (CH), 125.8 (CH), 125.1 (CH), 124.3 (C), 123.5 (C), 120.6 (CH), 120.1 (CH), 110.1 (CH), 109.4 (CH), 108.4 (CH) ppm.

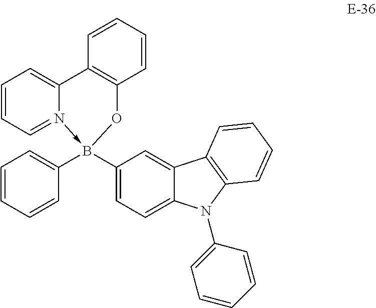 [SMILES: c1ccc(-n2c3ccccc3c3cc([B-]4(c5ccccc5)Oc5ccccc5-c5cccc[n+]54)ccc32)cc1]

General Procedure A was followed with the following changes: Borinic acid A5 (0.74 g, 2.1 mmol) was weighed into a glass jar with a PTFE-coated stirbar. The solid was dissolved in methylene chloride (10 mL). While stirring the reaction mixture, solid 2-(2-hydroxyphenyl)pyridine (0.368 g, 2.1 mmol) was added.

The solid was isolated in 36% yield (0.383 g). ¹H NMR (400 MHz, CD₂C1₂): δ 8.24 (ddd, J=6.0, 1.6, 0.8 Hz, 1H), 8.08-7.97 (m, 4H), 7.70 (dd, J=8.0, 1.6 Hz, 1H), 7.64-7.54 (m, 4H), 7.49-7.15 (m, 14H), 6.88 (ddd, J=8.3, 7.2, 1.2 Hz, 1H) ppm. ¹³C NMR (126 MHz, CD₂Cl₂): δ 160.8 (C), 151.2 (C), 144.7 (CH), 141.5 (CH), 141.3 (C), 140.9 (C), 138.6 (C), 134.7 (CH), 133.7 (CH), 132.2 (CH), 130.3 (CH), 127.7 (CH), 127.6 (CH), 127.4 (CH), 126.8 (CH), 126.1 (CH), 125.9 (CH), 125.6 (CH), 124.2 (C), 123.4 (C), 122.7 (CH), 121.5 (CH), 121.5 (CH), 120.6 (CH), 120.1 (CH), 119.8 (CH), 119.3 (C), 110.0 (CH), 109.2 (CH) ppm.

The structure was verified by single-crystal X-Ray Diffractometry on crystals of the product. The crystals were grown from methylene chloride/hexanes.

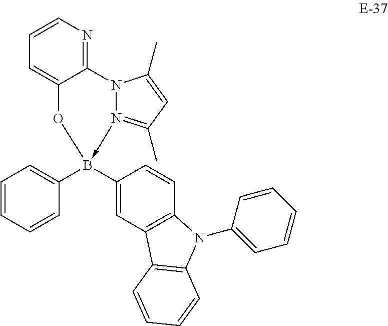 [SMILES: Cc1cc(C)[n+]2n1-c1ncccc1O[B-]2(c1ccccc1)c1ccc2c(c1)c1ccccc1n2-c1ccccc1]

General Procedure A was followed with the following changes: The borinic acid A5 (0.82 g, 2.4 mmol) was weighed into a glass jar with a PTFE-coated stirbar. The solid was dissolved in methylene chloride (15 mL). While stirring the reaction mixture, solid 2-(3,5-dimethyl-1H-pyrazol-1-yl)pyridin-3-ol (0.45 g, 2.4 mmol) was added.

All except 5 mL of the solvent was removed in vacuo. Hexanes (15 mL) was added, but no solid precipitated. Additional 40 mL hexanes was added; no solid precipitated. The mixture was placed under vacuum and about 5-10 mL of solvent was removed. A small amount of solid precipitated which was isolated and discarded. Another 30 mL of solvent was removed from the supernatant in vacuo. The resulting white solid was isolated by filtration (0.35 g, 28% yield). ¹H NMR (500 MHz, CD₂C1₂): δ 8.04-7.97 (m, 2H), 7.81 (dd, J=4.6, 1.5 Hz, 1H), 7.63-7.56 (m, 4H), 7.45 (dddd, J=8.7, 6.7, 4.5, 2.0 Hz, 2H), 7.40 (d, J=8.1 Hz, 1H), 7.34 (ddd, J=8.2, 6.9, 1.2 Hz, 1H), 7.32-7.28 (m, 2H), 7.27-7.16 (m, 6H), 7.14-7.10 (m, 1H), 6.24 (s, 1H), 2.87 (s, 3H), 1.76 (s, 3H) ppm. ¹³C NMR (126 MHz, CD₂Cl₂): δ 148.2, 147.2, 143.8, 141.3, 141.0, 141.0, 138.6, 137.5, 133.7, 132.2, 130.3, 128.6, 127.8, 127.6, 127.4, 127.0, 125.8, 125.6, 124.34, 124.33, 123.4, 120.6, 120.0, 111.4, 110.0, 109.3, 16.2, 14.5 ppm. ¹¹B NMR (160 MHz, CD₂Cl₂): δ 4.6 ppm.

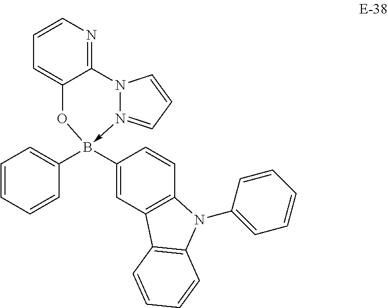 [SMILES: c1ccc(-n2c3ccccc3c3cc([B-]4(c5ccccc5)Oc5cccnc5-n5ccc[n+]54)ccc32)cc1]

General Procedure A was followed with the following changes: Borinic acid A5 (0.75 g, 2.2 mmol) was weighed into a glass vial with a PTFE-coated stirbar. The solid was dissolved in methylene chloride (12 mL). While stirring the reaction mixture, 2-(1H-pyrazol-1-yl)pyridin-3-ol (0.35 g, 2.2 mmol) was added and an additional 3 mL methylene chloride was added.

All except 5 mL of the solvent was removed in vacuo. Hexanes (12 mL) was added, but no solid formed. An additional 40 mL hexanes was added and an oily brown solid precipitated. The solid was isolated by filtration and discarded. The supernatant was placed under vacuum and about 20 mL of solvent was evaporated. The resulting white solid was isolated by filtration and dried under vacuum (0.34 g, 32% yield). ¹H NMR (500 MHz, CD₂Cl₂): δ 8.68 (dd, J=2.8, 1.0 Hz, 1H), 8.08-8.00 (m, 2H), 7.86 (dd, J=4.7, 1.4 Hz, 1H), 7.67 (dd, J=2.3, 1.1 Hz, 1H), 7.62-7.55 (m, 5H), 7.47-7.43 (m, 1H), 7.41-7.27 (m, 6H), 7.26-7.19 (m, 5H), 6.73 (t, J=2.6 Hz, 1H) ppm. ¹³C NMR (126 MHz, CD₂Cl₂): δ 146.8, 141.3, 141.1, 138.5, 138.4, 137.7, 137.5, 133.2, 131.6, 130.3, 129.5, 128.8, 127.9, 127.7, 127.5, 127.2, 125.9, 125.8, 125.1, 124.2, 123.5, 120.6, 120.1, 110.1, 109.3, 108.4 ppm. ¹¹B NMR (160 MHz, CD₂Cl₂): δ 4.8 ppm.

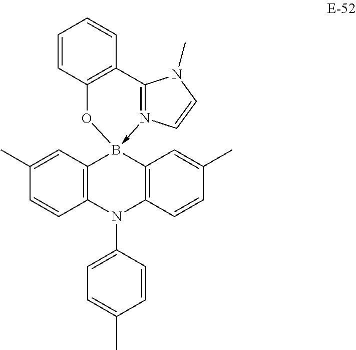

General Procedure A was followed with the following changes: The borinic acid A4 (0.105 g, 0.34 mmol) was dissolved in 8 mL methylene chloride and stirred with a PTFE-coated stirbar. While stirring, a 5 mL methylene chloride solution of 2-(2-hydroxyphenyl)-1-methylimidazole (0.058 g, 0.34 mmol) was added to the solution.

The resulting product (0.094 g, 60% yield) was characterized by NMR spectroscopy. ¹H NMR (500 MHz, CD₂Cl₂): δ 7.80 (dt, J=8.0, 1.6 Hz, 1H), 7.47-7.37 (m, 3H), 7.20 (dd, J=8.0, 1.7 Hz, 2H), 7.09 (d, J=2.2 Hz, 2H), 7.03 (dd, J=8.3, 1.4 Hz, 1H), 6.97-6.90 (m, 1H), 6.88 (d, J=1.7 Hz, 1H), 6.79 (dd, J=8.4, 2.1 Hz, 2H), 6.57 (t, J=1.7 Hz, 1H), 6.19 (dd, J=8.5, 1.5 Hz, 2H), 4.08 (d, J=1.5 Hz, 3H), 2.50 (s, 3H), 2.12 (s, 6H) ppm. ¹³C NMR (126 MHz, CD₂Cl₂): δ 160.2, 144.8, 141.8, 141.1, 137.9, 133.6, 133.1, 131.8, 131.8, 128.5, 127.8, 124.5, 124.0, 121.9, 121.0, 118.0, 114.7, 111.5, 38.0, 21.6, 20.8 ppm. ¹¹B NMR (160 MHz, CD₂Cl₂): δ 0.1 ppm.

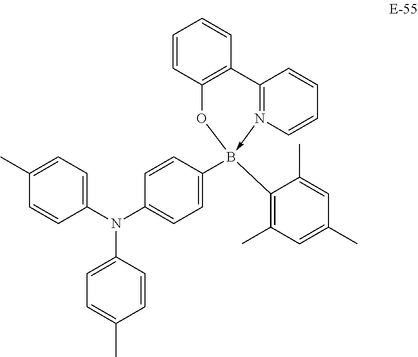

The reaction was set up in a nitrogen-purged glovebox. The borinic acid A6 (0.35 g, 0.83 mmol) was dissolved in methylene chloride (40 mL). 2-(Pyridine-2-yl)phenol (0.14 g, 0.83 mmol from ArkPharm) was added. The resulting mixture was stirred overnight at room temperature. The solution was combined with 40 mL toluene and placed under vacuum until only 30 mL solvent remained. The resulting solution was heated to 105° C. and kept at that temperature for 2 hours. After cooling to room temperature, solvent was removed in vacuo. The product was precipitated from methylene chloride/hexanes and rinsed with a small amount of toluene to leave the desired product (0.140 g, 29% yield) in >95% purity. ¹H NMR (500 MHz, CD₂Cl₂): δ 8.20 (dd, J=6.0, 1.8 Hz, 1H), 8.04 (t, J=7.8 Hz, 1H), 7.97 (d, J=8.3 Hz, 1H), 7.73 (dd, J=8.0, 1.6 Hz, 1H), 7.42-7.31 (m, 2H), 7.07 (dd, J=33.2, 8.0 Hz, 7H), 6.98-6.80 (m, 7H), 6.65 (s, 2H), 2.29 (s, 6H), 2.17 (s, 3H), 1.86 (s, 6H) ppm. ¹³C NMR (126 MHz, CD₂Cl₂): δ 160.2, 151.5, 147.1, 146.3, 145.3, 143.3, 141.6, 136.0, 134.6, 134.4, 132.4, 130.2, 125.9, 124.6, 123.0, 121.6, 121.0, 119.6, 119.5, 24.3, 21.0 ppm. ¹¹B NMR (160 MHz, CD₂Cl₂): δ 5.5 ppm.

### Synthesis of 4-carbazolylcatechol

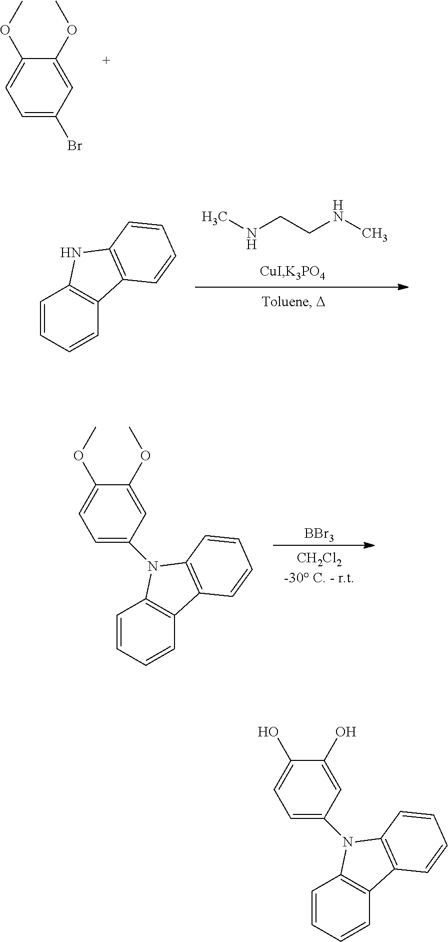

In a nitrogen-purged glovebox an oven dried 500 mL round bottom flask with a PTFE-coated magnetic stirbar was charged with dimethoxybromobenzene, carbazole, K₃PO₄, CuI, DMEDA and 300 ml of dry, degassed toluene. The flask was fitted with a reflux condenser and the mixture was heated to reflux for 17 hours. After cooling to room temperature, the mixture was removed from the glovebox and filtered through a plug of Celite® 545. The filtrate was concentrated under reduced pressure and the resulting material was taken up in 150 mL of ethyl acetate. The ethyl acetate layer was washed with water (3×150 mL) and brine (2×100 mL), and then dried over MgSO₄. The mixture was filtered and solvent was removed under reduced pressure. The resulting tan solid was recrystallized from hot absolute ethanol to give a first crop of the desired product (1.7 g, 24% yield). ¹H NMR (400 MHz, Chloroform-d) δ 8.17-8.12 (m, 2H), 7.41 (ddd, J=8.2, 6.9, 1.2 Hz, 2H), 7.35 (dt, J=8.1, 1.1 Hz, 2H), 7.28 (ddd, J=8.0, 6.9, 1.2 Hz, 2H), 7.13-7.01 (m, 3H), 3.99 (s, 3H), 3.87 (s, 3H).

In a nitrogen-purged glovebox the product, 9-(3,4-dimethoxyphenyl)-9H-carbazole (1.7 g, 5.6 mmol), from the previous step was added to a 100 mL jar with a PTFE-coated magnetic stirbar along with 40 mL of dry dichloromethane. The solution was placed in the glovebox freezer for 30 min to cool to −30° C. The jar was removed from the freezer and 2.5 mL of a 1.0 M solution of boron tribromide in dichloromethane was added slowly with stirring. The mixture was allowed to stir and come to room temperature for 5 hours. The jar was removed from the glovebox, carefully uncapped and 2 mL of water was added slowly. The mixture was transferred to a separatory funnel and 40 mL of water was added. The organic layer was separated and the aqueous layer was extracted with dichloromethane (3×30 mL). The combined organic layers were dried over MgSO₄ and evaporated under reduced pressure. The resulting colorless oil was triturated in 10 mL of hexanes and evaporated under reduced pressure three times to remove the residual dichloromethane and give the product as a light grey solid (77%). ¹H NMR (400 MHz, Chloroform-d) δ 8.13 (d, J=7.8 Hz, 2H), 7.42-7.36 (m, 2H), 7.34 (t, J=1.0 Hz, 2H), 7.27 (s, 2H), 6.99 (d, J=6.0 Hz, 3H), 5.47 (d, J=18.8 Hz, 2H), 5.28 (s, 4H).

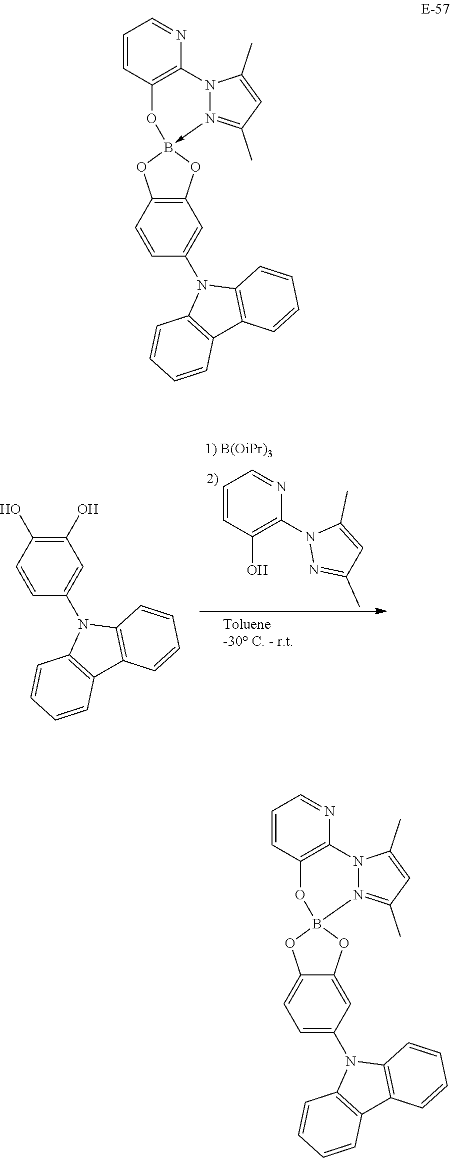

In a nitrogen-purged glovebox an oven-dried 20 mL vial with a PTFE-coated magnetic stirbar was charged with triisopropyl borate (0.092 mL, 0.399 mmol), 3 ml of dry, degassed toluene and the 4-carbazolylcatechol (100 mg, 0.363 mmol). The mixture was stirred at room temperature for 1 h, then placed in the glovebox freezer for 15 min to cool to −30° C. The vial was removed from the freezer and a solution of 2-pyridinylphenol (69 mg, 0.363 mmol) in 1 mL of toluene which had also been cooled in the glovebox freezer for 15 min was slowly added. The yellow mixture was allowed to stir and come to room temperature for 1 hour during which a white precipitate formed and the yellow color disappeared. The solvent was removed under reduced pressure to yield the desired product as a white solid. A yield was not determined. ¹H NMR (400 MHz, Chloroform-d) δ 8.16-8.09 (m, 2H), 8.01 (dd, J=4.6, 1.5 Hz, 1H), 7.55 (dd, J=8.1, 1.5 Hz, 1H), 7.44-7.37 (m, 4H), 7.28-7.26 (m, 1H), 7.25 (d, J=1.8 Hz, 1H), 7.01-6.97 (m, 2H), 6.94 (dd, J=8.2, 2.0 Hz, 1H), 6.29 (s, 1H), 2.94 (s, 3H), 2.30 (s, 3H).

Unexpectedly, it was found that delayed emission occurs with E-13 at room temperature, i.e., it exhibits thermally activated delayed fluorescence. The high energy onset of the delayed emission overlaps the onset of the prompt room temperature emission supporting the computational S1-T1 values and the conclusion that these molecules can undergo thermally activated delayed fluorescence.

Details summarizing the photophysical characterization of the Examples above are shown in Table 2. Comparative examples Comp-4, Comp-16, and Comp-33 demonstrate undesirable HOMO levels (<−5.5 eV) and have undesirably high S1-T1 values. The prior art exhibits an undesirably high S1-T1 gap. As seen in the table, proper selection of the first and second aromatic group by the addition of nitrogen atoms covalently bonded to the aromatic group along with the chelating group allows for tuning the HOMO, the LUMO is modified by the choice of chelating group, while the entire molecule can be designed within the parameters of the invention to adjust the triplet energy and the S1-T1 gap to facilitate the use of these materials in an electroluminescent device. The experimentally determined values are generally in good agreement with the computed values.

TABLE 2

| | | | | S₁-T₁ | | |
|---|---|---|---|---|---|---|
| | HOMO | LUMO | T₁ | Gap | exp T₁ | exp S₁-T₁ Gap |
| Compound | (eV) | (eV) | (eV) | (eV) | (eV) | (eV) |
| I-B-6* | −5.16 | −1.77 | 2.25 | 0.89 | | |
| CompEx-1 | −6.07 | −3.02 | 2.46 | 0.34 | 2.67 | 0.88 |
| CompEx-2 | −6.07 | −1.82 | 2.88 | 0.77 | 3.14 | 0.46 |
| CompEx-3 | −5.92 | −1.34 | 2.90 | 0.89 | 3.14 | 0.50 |
| E-11 | −4.97 | −1.90 | 2.45 | 0.26 | 2.77 | 0.28 |
| E-12 | −4.87 | −2.54 | 1.89 | 0.01 | 2.48 | 0.00 |
| E-13 | −4.66 | −2.02 | 2.41 | 0.04 | 2.76 | 0.06 |
| E-21 | −4.69 | −1.39 | 2.87 | 0.15 | 3.00 | 0.30 |
| E-22 | −5.07 | −1.44 | 2.90 | 0.55 | 3.00 | 0.24 |
| E-26 | −4.65 | −1.23 | 2.84 | 0.10 | 3.10 | 0.25 |
| E-27 | −4.46 | −1.19 | 2.79 | 0.07 | 3.10 | 0.21 |
| E-28 | −4.44 | −1.81 | 2.26 | 0.04 | 2.73 | 0.00 |
| E-31 | −5.03 | −1.52 | 2.84 | 0.32 | 3.06 | 0.58 |
| E-36 | −5.05 | −1.93 | 2.47 | 0.34 | 2.79 | 0.35 |
| E-37 | −5.00 | −1.32 | 2.89 | 0.49 | 3.10 | 0.57 |
| E-38 | −5.03 | −1.56 | 2.86 | 0.37 | 3.10 | 0.49 |
| E-52 | −4.28 | −1.14 | 2.60 | 0.01 | 2.85 | 0.25 |
| E-55 | −4.52 | −1.98 | 2.33 | 0.04 | 2.88 | 0.00 |
| E-57 | −4.91 | −1.69 | 2.82 | 0.01 | 3.06 | 0.65 |

Values are calculated using Density Functional Theory (DFT) at B3LYP/6-31g* level. Exp T1 and Exp S1-T1 gaps are measured experimentally from the emission spectra.
*Compound I-B-6 is the prior art compound whose structure is shown on page 1.

### OLED Device Fabrication and Testing

All organic materials were purified by sublimation before deposition. OLEDs were fabricated onto an ITO coated glass substrate that served as the anode, and topped with an aluminum cathode. All organic layers were thermally deposited by chemical vapor deposition, in a vacuum chamber with a base pressure of <10⁻⁷ torr. The deposition rates of organic layers were maintained at 0.1˜0.05 nm/s. The aluminum cathode was deposited at 0.5 nm/s. The active area of the OLED device was “3 mm×3 mm,” as defined by the shadow mask for cathode deposition.

Each cell, containing HIL1, HIL2, HTL1, HTL2, EBL, EML host, EML dopant, ETL1, ETL2, or EIL, was placed inside a vacuum chamber, until it reached 10⁻⁶ torr. To evaporate each material, a controlled current was applied to the cell, containing the material, to raise the temperature of the cell. An adequate temperature was applied to keep the evaporation rate of the materials constant throughout the evaporation process.

For the HIL1 layer, N4,N4′-diphenyl-N4,N4′-bis(9-phenyl-9H-carbazol-3-yl)-[1,1′-biphenyl]-4,4′-diamine was evaporated at a constant 1 Å1 A/s rate, until the thickness of the layer reached 600 Angstrom. Simultaneously, the dipyrazino[2,3-f:2′,3′-h[quinoxaline-2,3,6,7,10,11-hexacarbonitrile layer was evaporated at a constant 0.5 Å5 A/s rate, until the thickness reached 50 Angstrom. For the HTL1 layer, N-([1,1′-biphenyl]-4-yl)-9,9-dimethyl-N-(4-(9-phenyl-9H-carbazol-3-yl)phenyl)-9H-fluoren-2-amine was evaporated at a constant 1 Å1 A/s rate, until the thickness reached 150 Angstrom. For the HTL2 layer, N,N-di([1,1′-biphenyl]-4-yl)-4′-(9H-carbazol-9-yl)-[1,1′-biphenyl]-4-amine was evaporated at a constant 1 Å1 A/s rate, until the thickness reached 50 Angstrom. For the EBL layer, 1,3-di(9H-carbazol-9-yl)benzene was evaporated at a constant 1 Å1 A/s rate, until the thickness reached 50 Angstrom. For the EML layer, 9,9′,9″-(pyrimidine-2,4,6-triyl)tris(9H-carbazole) (host) and the dopant (D-1 or E-13) were co-evaporated, until the thickness reached 400 Angstrom. The deposition rate for host material was 0.85 Å85 A/s, and the deposition for the dopant material was 0.15 Å/s, resulting in a 15% doping of the host material. For the ETL1 layer, 5-(4-([1,1′-biphenyl]-3-yl)-6-phenyl-1,3,5-triazin-2-yl)-7,7-diphenyl-5,7-dihydroindeno[2,1-b]carbazole was evaporated at a constant 1 Å1 A/s rate, until the thickness reached 50 Angstrom. For the ETL2 layer, 2,4-bis(9,9-dimethyl-9H-fluoren-2-yl)-6-(naphthalen-2-yl)-1,3,5-triazine was co-evaporated with lithium quinolate(Liq), until the thickness reached 300 Angstrom. The evaporation rate for the ETL compounds and Liq was 0.5 Å/s. Finally, “20 Angstrom” of a thin electron injection layer (Liq) was evaporated at a 0.5 Å/s rate. See Table 2.

The current-voltage-brightness (J-V-L) characterizations for the OLED devices were performed with a source measurement unit (KEITHLY 238) and a luminescence meter (MINOLTA CS-100A). EL spectra of the OLED devices were collected by a calibrated CCD spectrograph and EQE was collected by a PR655.

TABLE 2
Device Materials

| | Name |
|---|---|
| Hole Injection | N4,N4′-diphenyl-N4,N4′-bis(9-phenyl-9H- |
| Material 1 | carbazol-3-yl)-[1,1′-biphenyl]-4,4′-diamine |
| Hole Injection | dipyrazino[2,3-f:2′,3′-h]quinoxaline-2,3,6,7,10,11- |
| Material 2 | hexacarbonitrile |
| Hole Transporting | N-([1,1′-biphenyl]-4-yl)-9,9-dimethyl-N-(4-(9- |
| Material1 | phenyl-9H-carbazol-3-yl)phenyl)-9H-fluoren-2- |
| | amine |
| Hole Transporting | N,N-di([1,1′-biphenyl]-4-yl)-4′-(9H-carbazol-9-yl)- |
| Material2 | [1,1′-biphenyl]-4-amine |
| Electron blocking | 1,3-di(9H-carbazol-9-yl)benzene |
| Material2 | |
| Host | 9,9′,9″-(pyrimidine-2,4,6-triyl)tris(9H-carbazole) |
| Dopant | 11-(4,6-diphenyl-1,3,5-triazin-2-yl)-12-phenyl- |
| | 11,12-dihydroindolo[2,3-a]carbazole |
| ETL1 | 5-(4-([1,1′-biphenyl]-3-yl)-6-phenyl-1,3,5-triazin- |
| | 2-yl)-7,7-diphenyl-5,7-dihydroindeno[2,1- |
| | b]carbazole |
| ETL2 | 2,4-bis(9,9-dimethyl-9H-fluoren-2-yl)-6- |
| | (naphthalen-2-yl)-1,3,5-triazine |
| Electron Injection | lithium quinolate |
| Material | |

### DEVICE COMPARATIVE EXAMPLE

The previous procedure was followed, except 11-(4,6-diphenyl-1,3,5-triazin-2-yl)-12-phenyl-11,12-dihydroindolo[2,3-a]carbazole (D-1, dopant) was used in place of E-13. As seen in the table below, the efficiency of the device fabricated with E-13 is higher than that of D-1.

### Device Result

| | Luminous | | |
|---|---|---|---|
| | Efficiency | | |
| | @1000 nit | CIE | EQE |
| | [Cd/A] | (X, Y) | (%) |
| D-1 | 8.9 | 271,468 | 3.7 |
| E13 | 13.4 | 299,513 | 4.0 |

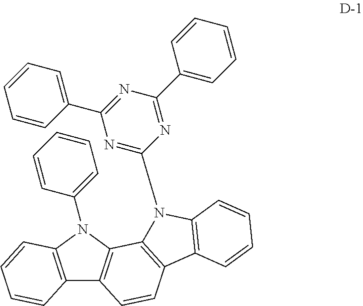 [SMILES: c1ccc(-c2nc(-c3ccccc3)nc(-n3c4ccccc4c4ccc5c6ccccc6n(-c6ccccc6)c5c43)n2)cc1]

1. A compound having a four-coordinate boron atom to which is connected a first C₃-C₂₅ substituent, a second C₃-C₂₅ substituent and a bridging substituent comprising from eight to forty non-hydrogen atoms and having two bonds to the boron atom;
wherein: (i) each of the first and second C₃-C₂₅ substituents is bonded to the boron atom through a carbon, nitrogen or oxygen atom, and, optionally the first and second C₃-C₂₅ substituents are connected to form a single substituent having two bonds to the boron atom; (ii) at least one of the first and second C₃-C₂₅ substituents is a C₆-C₂₅ aromatic substituent; (iii) said aromatic substituent comprises at least one nitrogen atom which is bonded only to carbon or boron atoms; and (iv) the bridging substituent has at least one oxygen, nitrogen, sulfur or phosphorus atom bonded to the boron atom and at least one aromatic ring.

2. The compound of claim 1 which has formula (I) 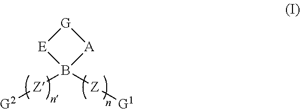
wherein Z and Z′ are NR¹¹ or O, where R¹ is hydrogen or deuterium, a C₆-C₂₅ aromatic substituent, or C₁-C₄ alkyl; n and n′ are 0 or 1; G¹ is the first C₃-C₂₅ substituent and G² is the second C₃-C₂₅ substituent; E is oxygen, nitrogen, sulfur or phosphorus; A is oxygen, nitrogen, sulfur or carbon; and G represents from five to forty atoms connecting E and A and forming at least one aromatic ring wherein G may include a substituent on E or A.

3. The compound of claim 2 which has formula (II) 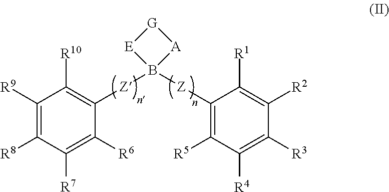
wherein R¹, R⁵, R⁶ and R¹⁰ are (i) hydrogen or deuterium, (ii) C₁-C₄ alkyl, (iii) one of IV and R⁵ joins with one of R⁶ and R¹⁰ to form a difunctional C₁-C₁₅ substituent which may include at least one nitrogen atom or silicon atom and which connects two aromatic rings, or (iv) one of R¹ and R⁵ and one of R⁶ and R¹⁰ joins with an R group on an adjacent ring carbon to form a C₅-C₇ fused ring; R², R⁴, R⁷ and R⁹ are hydrogen or deuterium, C₁-C₄ alkyl or R², R⁴, R⁷ or R⁹ joins with other R groups as indicated; R³ is: (i) hydrogen or deuterium, (ii) C₁-C₄ alkyl, (iii) a C₆-C20 aromatic substituent attached through a nitrogen atom, or (iv) R³ and one of R² and R⁴ join to form a C₆-C₂₀ aromatic substituent attached through a nitrogen atom and a carbon atom; R⁸ is: (i) hydrogen or deuterium, (ii) C₁-C₄ alkyl, (iii) a C₆-C₂₀ aromatic substituent attached through a nitrogen atom, or (iv) R⁸ and one of R⁷ and R⁹ join to form a C₆-C₂₀ aromatic substituent attached through a nitrogen atom and a carbon atom.

4. The compound of claim 3 in which R³ is a C₁₀-C₁₈ aromatic substituent attached through a nitrogen atom, or R³ and one of R² and R⁴ join to form a C₁₀-C₁₅ aromatic substituent attached through a nitrogen atom and a carbon atom; and R⁸ is a C₁₀-C₁₅ aromatic substituent attached through a nitrogen atom, or R⁸ and one of R⁷ and R⁹ join to form a C₁₀-C₁₈ aromatic substituent.

5. The compound of claim 4 in which G represents from eight to eighteen non-hydrogen atoms.

6. The compound of claim 5 in which E is nitrogen and A is oxygen or carbon.

7. The compound of claim 6 which has formula (III) 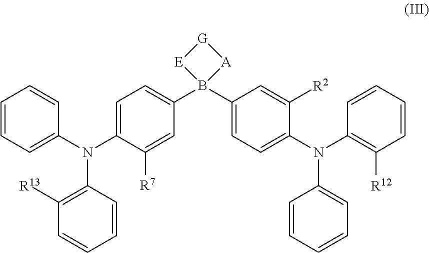
wherein R¹² represents hydrogen or deuterium, or R² and R¹² combine to form a single bond connecting two aromatic rings; and R¹³ represents hydrogen or deuterium, or R⁷ and R¹³ combine to form a single bond connecting two aromatic rings.

8. The compound of claim 7 in which G represents from ten to sixteen non-hydrogen atoms.

9. The compound of claim 3 which has formula (IV) 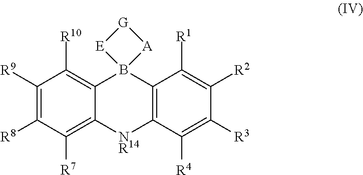
wherein R¹⁴ is a C₆-C₁₅ aromatic substituent.

10. The compound of claim 9 in which G represents from eight to eighteen non-hydrogen atoms.

11. The compound of claim 10 in which E is nitrogen and A is oxygen or carbon.

12. A light-emitting device comprising at least one compound of claim 1.

13. The light-emitting device of claim 12 in which said at least one compound is present in an emitter layer.

14. The light emitting device of claim 13 in which said at least one compound has formula (II) 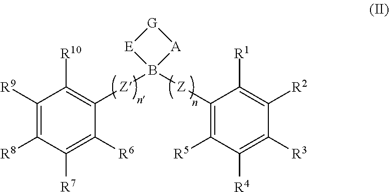
wherein Z and Z′ are NR¹¹ or O, where R¹¹ is hydrogen or deuterium, a C₆-C₂₅ aromatic substituent, or C₁-C₄ alkyl; n and n′ are 0 or 1; R¹, R⁵, R⁶ and R¹⁰ are (i) hydrogen or deuterium, (ii) C₁-C₄ alkyl, (iii) one of R¹ and R⁵ joins with one of R⁶ and R¹⁰ to form a difunctional C₁-C₁₅ substituent which may include at least one nitrogen atom or silicon atom and which connects two aromatic rings, or (iv) one of R¹ and R⁵ and one of R⁶ and R¹⁰ joins with an R group on an adjacent ring carbon to form a C₅-C₇ fused ring; R², R⁴, R⁷ and R⁹ are hydrogen or deuterium, C₁-C₄ alkyl or R², R⁴, R⁷ or R⁹ joins with other R groups as indicated; R³ is: (i) hydrogen or deuterium, (ii) C₁-C₄ alkyl, (iii) a C₆-C₂₀ aromatic substituent attached through a nitrogen atom, or (iv) R³ and one of R² and R⁴ join to form a C₆-C₂₀ aromatic substituent attached through a nitrogen atom and a carbon atom; R⁸ is: (i) hydrogen or deuterium, (ii) C₁-C₄ alkyl, (iii) a C₆-C₂₀ aromatic substituent attached through a nitrogen atom, or (iv) R⁸ and one of R⁷ and R⁹ join to form a C₆-C₂₀ aromatic substituent attached through a nitrogen atom and a carbon atom; E is oxygen, nitrogen, sulfur or phosphorus; A is oxygen, nitrogen, sulfur or carbon; and G represents from five to forty atoms connecting E and A and forming at least one aromatic ring wherein G may include a substituent on E or A.

15. The light-emitting device of claim 13 in which the emitter layer further comprises a light-emitting material which comprises iridium or platinum.

16. The light-emitting device of claim 15 in which the emitter layer further comprises 9,9′,9″-(pyrimidine-2,4,6-triyl)tris(9H-carbazole).
